(19) United States
(12) Patent Application Publication
(10) Pub. No.: US 2026/0299442 A1
(43) Pub. Date: Oct. 1, 2026

(54) CLEANING STRUCTURE SURFACE IN LIGHT SOURCE CHAMBER

(71) Applicant: ASML Netherlands B.V., Veldhoven (NL)

(72) Inventors: Pitam Mitra, San Diego, CA (US); John Charles Hirschy Wick, Encinitas, CA (US)

(21) Appl. No.: 19/480,590

(22) PCT Filed: May 20, 2024
(86) PCT No.: PCT/EP2024/063863

§ 371 Date: Oct. 31, 2025

Related U.S. Application Data
(60) Provisional application No. 63/503,542, filed on May 22, 2023.
(60) Provisional application No. 63/640,407, filed on Apr. 30, 2024.

(51) Int. Cl. G03F 7/00

(52) U.S. Cl. CPC G03F 7/70925; G03F 7/70033; G03F 7/70916

(57) ABSTRACT

An apparatus includes: a component of a chamber of an extreme ultraviolet (EUV) light source, the component including at least one exposed surface; and a cleaning apparatus configured to remove target debris from the exposed surface of the component without separating the component from the chamber. The cleaning apparatus includes: one or more surface-wave plasma (SWP) generators, with each SWP generator being disposed in a groove formed in the exposed surface of the component; and, for each SWP generator, a shield placed between the chamber and the SWP generator. The shield, the SWP generator, and the exposed surface define at least one open channel between the SWP generator and the chamber, the open channel extending across the groove.

### CROSS-REFERENCE TO RELATED APPLICATIONS

This application claims priority of U.S. Application No. 63/503,542, which was filed on May 22, 2023, titled CLEANING STRUCTURE SURFACE IN LIGHT SOURCE CHAMBER, and U.S. Application No. 63/640,407, which was filed on Apr. 30, 2024, titled CLEANING STRUCTURE SURFACE IN LIGHT SOURCE CHAMBER, which are incorporated herein in its entirety by reference.

### TECHNICAL FIELD

The disclosed subject matter relates to a system and method for cleaning debris from a surface of a structure within a chamber of an extreme ultraviolet light source.

### BACKGROUND

Extreme ultraviolet (EUV) light, for example, electromagnetic radiation having wavelengths of around 50 nanometers (nm) or less (also sometimes referred to as soft x-rays), and including light at a wavelength near 13.5 nm (for example, in a range of about 13.36 nm-13.65 nm at 50% power), can be used in photolithography processes to produce extremely small features in substrates, for example, silicon wafers. EUV light can also be employed in the inspection process to identify defects and perform precise measurement as well as material analysis in semiconductor manufacturing processes. Methods to produce EUV light include, but are not necessarily limited to, converting a material that has an element, for example, xenon, lithium, or tin, with an emission line in the EUV range in a plasma state. In one such method, often termed laser produced plasma (“LPP”), the required plasma can be produced by irradiating a target material, for example, in the form of a droplet, plate, tape, stream, or cluster of material, with an amplified light beam. For this process, the plasma is typically produced in a sealed vessel, for example, a vacuum chamber, and monitored using various types of metrology equipment.

### SUMMARY

In some general aspects, an apparatus includes: a component of a chamber of an extreme ultraviolet (EUV) light source, the component including at least one exposed surface; and a cleaning apparatus configured to remove target debris from the exposed surface of the component without separating the component from the chamber. The cleaning apparatus includes: one or more surface-wave plasma (SWP) generators, with each SWP generator being disposed in a groove formed in the exposed surface of the component; and for each SWP generator, a shield placed between the chamber and the SWP generator. The shield, the SWP generator, and the exposed surface define at least one Clean Version open channel between the SWP generator and the chamber, the open channel extending across the groove.

Implementations can include one or more of the following features. For example, the SWP generator can include an inner electrical conductor extending along an axial direction of the groove of the component and a dielectric insulator outside of the inner electrical conductor and extending along the axial direction, the dielectric insulator in contact with a groove surface and the shield in contact with the dielectric insulator. The dielectric insulator may surround the inner electrical conductor. The axial direction of the inner electrical conductor can be parallel to the exposed surface. The shield can be made of a heat conductive and rigid material that is non-reactive with a target within the chamber that produces the EUV light. The shield can include or be made of aluminum, aluminum oxide, steel, iron, copper, stainless steel, an alloy of nickel including chromium and iron, molybdenum, or a carbon-based steel alloy. Each respective shield can be positioned with an inner surface in contact with its SWP generator and an outer surface flush with the exposed surface. Each SWP generator can make contact with a groove surface at at least one interface. In operation, each SWP generator can radiate electromagnetic energy, which transforms a material that is present in the chamber from a first state into a plasma state that includes plasma particles, and the plasma particles and the exposed surface of the component can form a waveguide for the propagation of the electromagnetic energy, the waveguide at least partly in the open channel. In operation, part of the guided electromagnetic energy can continue to transform material present in the chamber at another location along the waveguide into the plasma state that includes plasma particles. In operation, at least some of the plasma particles can be free radicals and ions of the material, such that the plasma particles come in contact with the debris on the exposed surface of the component. Each SWP generator can radiate electromagnetic energy at a microwave frequency. The open channel, in operation, can enable passage of the electromagnetic energy and the plasma particles from the exposed surface of the component along the waveguide. The material present in the chamber that is transformed can be in a gas state. The cleaning apparatus can include at least two SWP generators and fewer than 26 SWP generators, with each SWP generator being in contact with a distinct portion of the exposed surface of the component. The component can include a conical liner positioned between a collector mirror and an intermediate focus of the collector mirror, the liner including an exposed surface that, when installed, faces EUV light that is reflected from the collector mirror toward the intermediate focus. The liner can be made of an electrically-conductive material. Each SWP generator can extend along an axial path of the exposed surface of the liner, the axial path extending from the collector mirror side at one end to the intermediate focus side at the other end. The component can be electrically-conductive. The shield can be in contact with the SWP generator.

In other general aspects, a method is performed for cleaning an exposed conducting surface of a component of a chamber of an extreme ultraviolet (EUV) light source. The method includes: removing target debris from the exposed conducting surface of the component without separating the component from the chamber. Removing includes: generating microwave radiation from an antenna that extends axially along a groove formed within the exposed conducting surface; enabling the microwave radiation to ionize gas present at the exposed conducting surface to form a surface-wave plasma (SWP) at the exposed conducting surface of the component; enabling the generated surface-wave plasma SWP to spread along the exposed conducting surface such that a waveguide is generated between the SWP and the exposed conducting surface; and shielding the antenna from radiation and targets within the chamber and dissipating heat away from the antenna.

Implementations can include one or more of the following features. For example, the shielding can be provided by a shield that extends along the antenna. The removing can also include permitting microwave radiation and the SWP to escape along the waveguide. The exposed conducting surface can be grounded.

In other general aspects, an extreme ultraviolet (EUV) light source includes: a vessel defining a chamber that receives targets at an interaction region; a component of the chamber, the component including an exposed surface; and a cleaning apparatus configured to remove target debris from the exposed surface of the component without separating the component from the chamber. The cleaning apparatus includes: one or more surface-wave plasma (SWP) generators, with each SWP generator disposed axially in a groove extending along the exposed surface such that the SWP generator is in contact with a portion of a surface of the groove ; and, for each SWP generator, a shield placed between the chamber and the SWP generator extending over the SWP generator and extending axially along the groove. The shield, the SWP generator, and the exposed surface define at least one open channel from the SWP generator to the chamber.

Implementations can include one or more of the following features. For example, the shield can be in contact with the SWP generator. The SWP generator can include an inner electrical conductor extending along an axial path of the groove and a dielectric insulator outside of the inner electrical conductor and extending along the axial path. The dielectric insulator can be in contact with at least one surface of the groove and the shield can contact the dielectric insulator.

In other general aspects, an apparatus includes a cleaning apparatus configured to remove target debris from an exposed surface of a component of a chamber of an extreme ultraviolet (EUV) light source without separating the component from the chamber. The cleaning apparatus includes: one or more surface-wave plasma (SWP) generators, with each SWP generator being disposed in a groove formed in the exposed surface of the component; and, for each SWP generator, a shield placed between the chamber and the SWP generator. The shield, the SWP generator, and the exposed surface define at least one open channel between the SWP generator and the chamber, the open channel extending across the groove.

In other general aspects, an apparatus includes: a debris flow apparatus configured to direct and deposit target debris to one or more surfaces in or adjacent to a chamber of an extreme ultraviolet (EUV) light source; and a cleaning apparatus configured to remove the target debris at the one or more surfaces. The cleaning apparatus includes an active etching device configured to etch the target debris that has been deposited on the one or more surfaces.

Implementations can include one or more of the following features. For example, the one or more surfaces can include one or more of: a location within a conical liner positioned between a collector mirror and an intermediate focus of the collector mirror, the liner including an exposed surface that, when installed, faces EUV light that is reflected from the collector mirror toward the intermediate focus; a location within the conical liner that is adjacent an exhaust opening fluidly communicating with a removal apparatus; and a location within the exhaust opening or the removal apparatus. The active etching device can include at least one of a: surface-wave plasma (SWP) generator, inductively-coupled plasma (ICP) generator, radio-frequency (RF) discharge plasma generator, indirect plasma generator, microwave discharge generator, direct current discharge generator, electron cyclotron resonance plasma generator, and direct plasma generator. The debris flow apparatus can include one or more gas flows that are directed toward the one or more surfaces. The debris flow apparatus can include a flow controller configured to adjust the one or more gas flows.

The details of one or more implementations are set forth in the accompanying drawings and the description below. Other features will be apparent from the description and drawings, and from the claims.

### DRAWING DESCRIPTION

The accompanying drawings, which are incorporated herein and form part of the specification, illustrate the present disclosure and, together with the description, further serve to explain the principles of the present disclosure and to enable a person skilled in the relevant art(s) to make and use implementations described herein.

FIG. 1 is a schematic block diagram of a cleaning apparatus configured to clean debris off an exposed surface of a component of a chamber, the cleaning apparatus including a surface-wave plasma (SWP) generator and a shield between the SWP generator and the chamber;

FIG. 2A is a schematic cross-sectional close-up view of the cleaning apparatus and exposed surface of the component, in which the SWP generator generates a surface-wave plasma that travels along the exposed surface;

FIG. 2B is the schematic cross-sectional close-up view of FIG. 2A at a later time when the surface-wave plasma has traveled along the exposed surface;

FIGS. 3A-3C are schematic cross-sectional close-up views showing operation of the SWP generator of FIGS. 2A and 2B, in which FIG. 3A shows the production of the surface-wave plasma relative to the exposed surface, FIG. 3B shows plasma particles coming in contact with debris on the exposed surface, and FIG. 3C shows the plasma particles chemically reacting with the deposited particles of the debris to form a new chemical that is released from the exposed surface;

FIG. 4 is a top cross-sectional view of an implementation of the cleaning apparatus of FIG. 2A taken along the 4-4 plane;

FIG. 5 is a schematic view of an implementation of the vessel that can be a part of an EUV light source, in which the vessel defines a chamber and one or more cleaning apparatuses of FIG. 1 can be configured relative to a component of the chamber;

FIG. 6 is a side cross-sectional view of an implementation of the vessel of FIG. 5 that is made up of a plurality of pieces;

FIG. 7A is a bottom view of an implementation of a base sub-liner in the vessel of FIG. 6, in which the base sub-liner includes four cleaning apparatuses;

FIG. 7B is a perspective top view of the base sub-liner of FIG. 7A;

FIG. 8 is a bottom view of an implementation of a base sub-liner in the vessel of FIG. 6, in which the base sub-liner includes twelve cleaning apparatuses;

FIG. 9 is a bottom view of an implementation of a base sub-liner in the vessel of FIG. 6, in which the base sub-liner includes two cleaning apparatuses;

FIG. 10 is a perspective view of an implementation of a collector and an implementation of a shroud within the vessel of FIG. 5, in which one or more cleaning apparatuses can be used to clean a surface of the collector and one or more cleaning apparatuses can be used to clean a surface of the shroud;

FIG. 11A is a top side view of an implementation of a U-shaped shroud of FIG. 10, in which two cleaning apparatuses are used to clean outer surfaces of the shroud;

FIG. 11B is a cross-sectional view of the U-shaped shroud of FIG. 11A taken along the plane 11B-11B;

FIG. 12 is a procedure performed by the cleaning apparatus of FIG. 1;

FIGS. 13A-13E are bottom views of the base sub-liner of FIG. 7A as it is being cleaned with the four cleaning apparatuses taken at times tA, tB, tC, tD, and tE with time tB later than time tA, time tC later than time tB, time tD later than time tC; and time tE later than time tD;

FIG. 14 is a schematic illustration of an implementation of a lithography exposure apparatus that receives EUV light produced by the EUV light source of FIG. 5;

FIG. 15A is a top side view of an implementation of a U-shaped shroud of FIG. 10, in which two cleaning apparatuses are used to clean outer surfaces of the shroud;

FIG. 15B is a cross-sectional view of the U-shaped shroud of FIG. 15A taken along the plane 15B-15B;

FIG. 16A is a top side view of an implementation of a U-shaped shroud of FIG. 10, in which two cleaning apparatuses are used to clean outer surfaces of the shroud;

FIG. 16B is a cross-sectional view of the U-shaped shroud of FIG. 16A taken along the plane 16B-16B;

FIG. 17A is a top side view of an implementation of a U-shaped shroud of FIG. 10, in which two cleaning apparatuses are used to clean outer surfaces of the shroud;

FIG. 17B is a cross-sectional view of the U-shaped shroud of FIG. 17A taken along the plane 17B-17B;

FIG. 18 is a schematic block diagram of an apparatus including: a debris flow apparatus and a cleaning apparatus, the debris flow apparatus configured to direct debris to one or more surfaces in or adjacent to a chamber of an EUV light source;

FIG. 19 is a schematic view of an implementation of an apparatus that is designed with a vessel of an EUV light source, the apparatus including: a debris flow apparatus and a cleaning apparatus positioned relative to a surface; and

FIG. 20 is a schematic view of another implementation of an apparatus that is designed with a vessel of an EUV light source, the apparatus including: a debris flow apparatus and a cleaning apparatus positioned relative to a surface.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DESCRIPTION

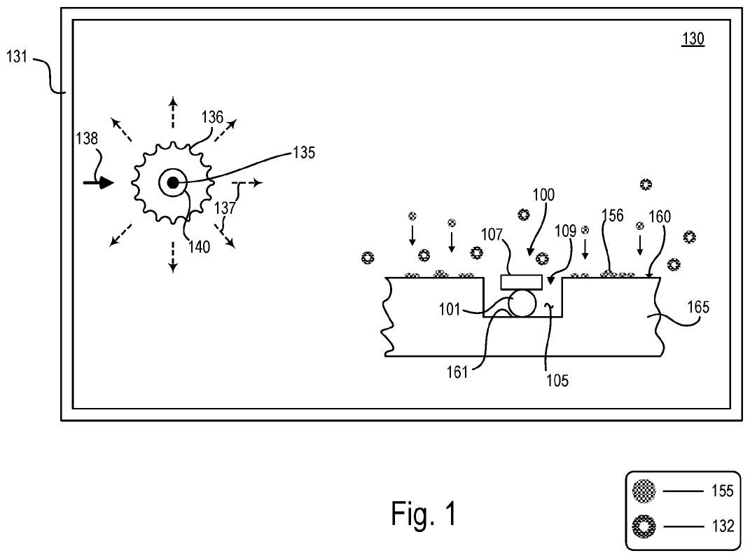

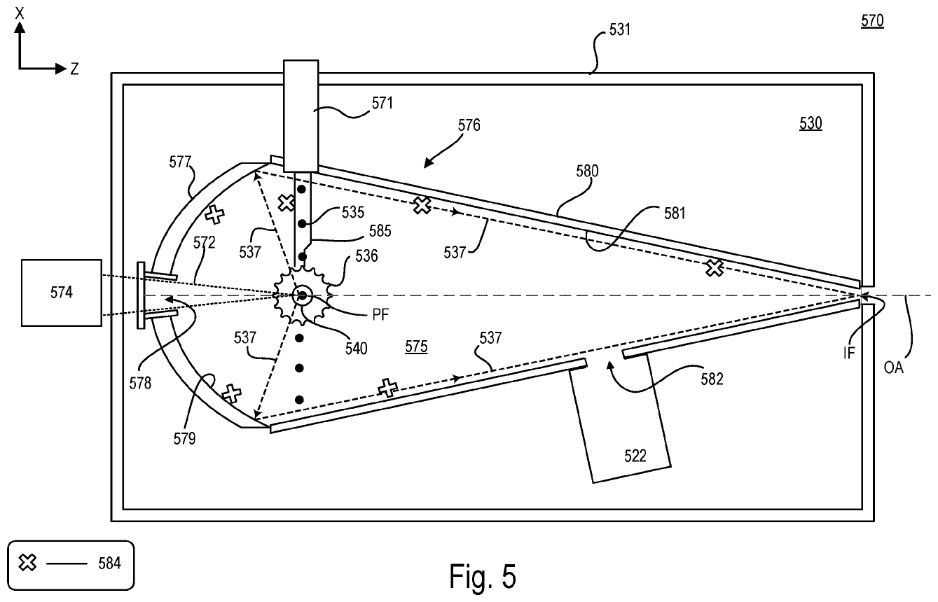

Referring to FIG. 1, a cleaning apparatus 100 is designed to clean debris 156 off of an exposed surface 160 of a component 165 of a chamber 130. The cleaning apparatus 100 includes a surface-wave plasma (SWP) generator 101 positioned near the exposed surface 160 of the component 165 as well as a shield 107 between the SWP generator 101 and the chamber 130. The exposed surface 160 is electrically conducting and electrically grounded. The chamber 130 is defined within a vessel 131 of an extreme ultraviolet (EUV) light source. An example of an EUV light source is shown in FIG. 5. The component 165 can be entirely within the vessel 131 (as shown in FIG. 1) or it can make up a part of the vessel 131 so that it includes the exposed surface 160 that faces the chamber 130. The cleaning apparatus 100 operates to clean the debris 156 off the exposed surface 160 without having to separate (such as remove or detach) the component 165 from the chamber 130. Stated alternatively, the cleaning can take place in-situ. The cleaning apparatus 100 additionally can operate to clean the debris 156 off the exposed surface 160 even during operation of the EUV light source and while EUV light 137 is being produced. While a single cleaning apparatus 100 and a single component 165 are shown in FIG. 1, there can be more than one cleaning apparatus 100 associated with a single component 165 and there can be more than one component 165 that is being cleaned with the cleaning apparatus 100. Moreover, while not shown in FIG. 1 for clarity, other devices and modules can be inside the chamber 130 or fixed to the vessel 131.

In general, targets 135 are provided at a region 140 within the chamber 130. The targets 135 include matter that emits EUV light 137 when the matter is converted into a light-emitting plasma 136 upon interaction with an energy pulse 138 (such as a pulse of an amplified light beam) in the region 140. The EUV light 137 and light-emitting plasma 136 shown in FIG. 1 can be produced from a prior target 135 in the region 140 that has interacted with a prior energy pulse. The debris 156 is at least partially produced from leftover or remaining target matter 155 in the chamber 130. In particular, the leftover or remaining target matter 155 can be target matter within the target 135 that is not converted into the light-emitting plasma in the region 140 and/or the leftover or remaining target matter 155 can be produced from light-emitting plasma that reverts back into target matter 155. The process of generating the EUV light 137 relies on converting the matter in many targets 135 into light-emitting plasma 136, and thus a large amount of remaining or leftover target matter 155 can be produced in the process. Different phases of the target matter 155 tend to deposit on surfaces of various objects inside the chamber 130. The target matter 155 that remains or is leftover can travel through the chamber 130 and coat various objects such as walls, optical elements, and components within the chamber 130. As shown in FIG. 1, target matter 155 has deposited onto the surface 160 of the component 165 to form the debris 156. The debris 156 that forms on the surfaces of these objects (including the surface 160 of the component 165) can include vapor residue, ions, particles, and/or clusters of matter formed from the target matter 155.

The debris 156 can severely impair the performance of the EUV light source by blocking the EUV light 137 and/or by contaminating the components of or within the chamber 130. The debris 156 forms a coating on the surface 160 that effectively blocks the surface 160. Thus, if the surface 160 is an optical surface that is meant to interact with light in the chamber 130, its efficiency will drop as it becomes coated with debris 156. As another example, if the surface 160 is a non-optical surface (that does not interact with light), then the debris 156 coating the surface 160 can cause other serious problems within the chamber 130. The debris 156 can cause the surface 160 and the component 165 to heat up, which can lead to the debris 156 being ejected from the surface 160 and onto other objects within the chamber 130. The debris 156 can cause other problems that lead to a reduction in the production of EUV light 137. For example, the debris 156 can be flaked off, dropped off, spit off, or dripped off the surface 160. In summary, the presence of such debris 156 can reduce the performance of the surfaces within the chamber 130 and reduce the overall efficiency of the EUV light source and production of EUV light 137. As discussed below, if the target 135 includes molten metal of tin, then tin particles, clusters of tin, tin residue, or tin ions can accumulate on (or coat) one or more components 165 within the chamber 130.

The debris 156 can be produced from materials other than the target matter that are present within the chamber 130. For example, the debris 156 can include carbon.

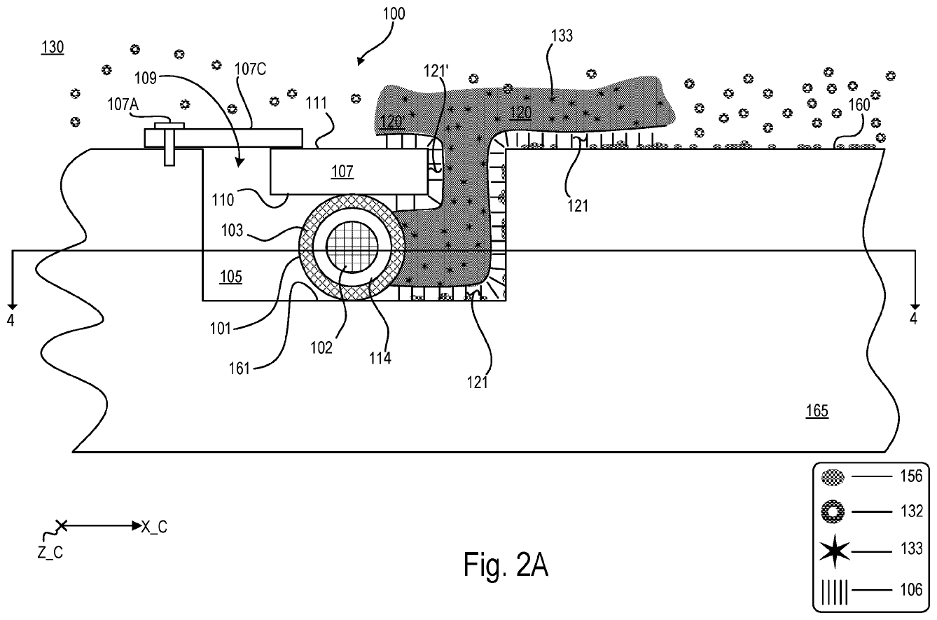

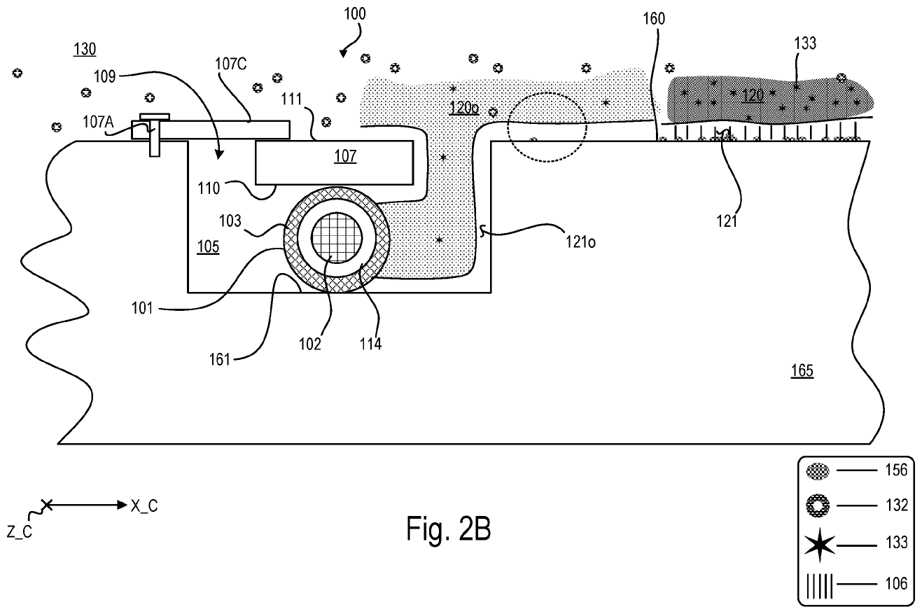

In FIG. 1, only one cleaning apparatus 100 is shown, but, as discussed above and also below, there can be more than one cleaning apparatus 100 associated with a component 165. Moreover, each cleaning apparatus 100 can include more than one SWP generator 101. The SWP generator 101 is in contact with a groove surface 161 formed by a groove 109 that is defined in the component 165. The groove 109 is formed in and extends below the exposed surface 160 of the component 165. An open channel 105 is formed in the groove 109. The SWP generator 101 can be an antenna, having a conductive structure (the conducting element 102 of FIGS. 2A and 2B) that transmits electromagnetic radiation or waves.

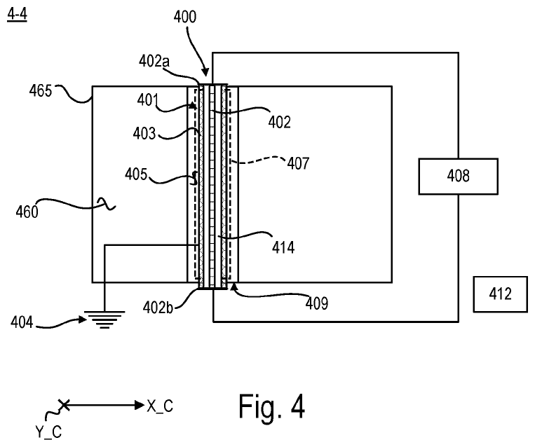

As shown in FIGS. 2A and 2B, which are close-up views of the cleaning apparatus 100, in some implementations, the SWP generator 101 has a linear geometry that includes an inner electrical conductor or conducting element 102 such as a rod or a wire extending along a local axial path Z_C (which is into and out of the page) of the groove 109 and a coaxial dielectric insulator 103 outside the conducting element 102, the insulator 103 extending as well along the axial path Z_C. In the illustrated embodiment the insulator 103 surrounds the conducting element 102. A space or a gap 114 between the conducing element 102 and the insulator 103 can be filled with, for example, air. The gap 114 ensures that any plasma that is produced (as discussed below) is well separated from the conducting element 102 so that there is a reduced or zero change of arcing between the plasma and the conducting element 102. In order to ensure that the gap 114 is maintained, ends 402a, 402b (see FIG. 4) of the conducting element 102 and insulator 103 can be sealed (such as joined by, for example brazing). The gap 114 also helps move the produced plasma away from the conducting element 102 so that a suitable density of the plasma is maintained. In one specific non-limiting example, a diameter of the conducting element 102 (in the X_C, Y_C plane) is a value in the range of about 1-4 millimeters (mm) and an inner diameter of the insulator 103 (in the X_C, Y_C plane) is a value in the range of about 5-8 mm. The insulator 103 is in contact with the groove surface 161. Current is flowed through the conducting element 102, as discussed in more detail with reference to FIG. 4.

As shown in the close-up views of FIGS. 2A and 2B, the SWP generator 101 generates electromagnetic energy or radiation 106 when current is flowed through the conducting element 102. The electromagnetic radiation 106 can be at a microwave frequency and thus, in this case, the SWP generator 101 generates microwave radiation. And, this electromagnetic radiation 106 transforms material 132 that is present in the chamber 130 from a first state of matter (for example, gas, vapor, or liquid) into a plasma state of matter (or simply referred to as a “plasma”), which is labeled as 120. The material 132 is shown in the first state of matter in FIG. 1. The material 132 can be transformed by, for example, ionization. The plasma 120 that is produced from the interaction of the electromagnetic radiation 106 and the material 132 is referred to as a surface-wave plasma. The surface-wave plasma 120 includes, among other materials, plasma particles 133.

The surface-wave plasma 120 is a self-guided plasma that naturally spreads over the groove surface 161 and the surface 160 of the component 165 and naturally forms a waveguide 121 (which can be considered a lossy waveguide). Thus, the plasma 120 is created by the electromagnetic radiation 106 (interacting with the material 132), but the plasma 120 also reflects and guides this same electromagnetic radiation 106 along the surface (the groove surface 161 and the surface 160 of the component 165). The waveguide 121 is the region or space between the surface-wave plasma 120 and the surface 160 or the groove surface 161 of the component 165. For example, FIG. 2B shows the state of the surface-wave plasma 120 at a later time than the time shown in FIG. 2A. In FIG. 2B, the guided electromagnetic radiation 106 has transformed the material 132 present at a location along the +X_C direction along the surface 160 relative to the location in FIG. 2A, and therefore, the surface-wave plasma 120 has spread along the surface 160 of the component 165 away from the SWP generator 101 along the +X_C direction. The previously-created surface-wave plasma is represented as 1200 and the previously-created waveguide is represented as 1210. There are fewer plasma particles 133 in the older surface-wave plasma 1200 because many of the plasma particles 133 in the older surface-wave plasma 1200 have been used to etch the debris 156 from the groove surface 160 or the surface 161 of the component 165. Beyond the time snapshot of FIG. 2B, the radiation 106 continues to travel along the surface 160 within the waveguide 121 along the +X_C direction.

It should be noted that the electromagnetic radiation 106 is created in all of the open spaces that surround the SWP generator 101, and not just to the right of the SWP generator 101 in the plane of the page shown in FIG. 2A. The electromagnetic radiation 106 is therefore created to the left of the SWP generator 101 as well, and some surface-wave plasma 120 can be created to the left of the SWP generator 101. Some or most of the surface-wave plasma 120 created to the left of the SWP generator 101 may be blocked from traveling by other objects placed near the SWP generator 101 and the surface 160, such as, for example, the shield 107 and a clamp 107c (which are discussed in detail below).

Additionally, the views of FIGS. 2A and 2B are taken along the X_C, Y_C plane but it should be noted that the SWP generator 101 extends into and out of the page (along the Z_X direction) and therefore electromagnetic radiation 106 (and therefore the surface-wave plasma 120) is generated in locations along the SWP generator 101 at locations into and out of the page.

The radiation 106 travels along the surface 160 a distance that depends on the amount of power supplied to the conducting element 102, a pressure of the material 132, and a composition of the material 132. Moreover, the rate at which the debris 156 is removed (via etching) from the surface 160 is directly related to a pressure at which the chamber 130 is held. Thus, for example, a lower pressure in the chamber 130 correlates to a higher rate of etching and a higher pressure in the chamber 130 correlates to a lower rate of etching. The chamber 130 can be maintained at a pressure of about 165 pascals (Pa).

The volume of the lossy waveguide 121 has a lateral dimension that extends over several wavelengths of the electromagnetic radiation. For example, for microwaves of 2.45 GHz in a vacuum, the wavelength amounts to 12.2 centimeters (cm). As another example, for microwaves of 900 MHz in a vacuum, the wavelength amounts to 33 cm.

The chamber 130 is not a hospitable environment for the SWP generator 101. In particular, the SWP generator 101 is exposed to all of the possible debris materials (including targets 135) that can coat the components 165 (and surfaces 160 of the components 165) of the chamber 130. Moreover, the SWP generator 101 can also be exposed to the EUV light 137 that is produced when the targets 135 are converted into the light-emitting plasma 136. Additionally, the SWP generator 101 can also be exposed to light at other wavelengths (such as, for example, infrared radiation) that is produced when targets 135 are converted into the light-emitting plasma 136. Such infrared radiation can produce heat, which can cause the SWP generator 101 to heat up to a temperature that is greater than an acceptable operating temperature.

Because of this, the cleaning apparatus 100 includes, for each SWP generator 101, the shield 107 placed between the chamber 130 and the SWP generator 101. In some implementations, the shield 107 is in contact with the SWP generator 101. The shield 107 is configured to shield the SWP generator 101 from the inhospitable environment within the chamber 130. Additionally, the shield 107 can be configured to efficiently dissipate heat from the SWP generator 101.

The open channel 105 is therefore defined by the shield 107, the SWP generator 101, the exposed surface 160, and the groove surface 161). The open channel 105 enables the material 132 to enter the space near the exposed surface 160 and the groove surface 161 that is closest to the SWP generator 101 so that the generated electromagnetic radiation 106 is able to access and interact with the material 132. Moreover, the open channel 105 enables the surface-wave plasma 120 to naturally spread over the surface 160 of the component 165 (and the groove surface 161) and to naturally form the waveguide 121 without restrictions. The open channel 105 also enables the passage of microwave radiation 106 and the plasma particles 133 from the exposed surface 160/161 along the waveguide 121.

The shield 107 can be made of a heat conductive and rigid material that is non-reactive with the target 135. The shield 107 can be heat conductive in order to remove heat produced by the SWP generator 101 while the SWP generator 101 is operating. For example, the shield 107 can be made of aluminum, aluminum oxide, steel, iron, copper, stainless steel, an alloy of nickel including chromium and iron (such as Inconel), molybdenum, or a carbon-based steel alloy.

As shown in more detail in FIGS. 2A and 2B, the SWP generator 101 is positioned in the groove 109 that is formed in the exposed surface 160. The groove surface 161 is defined as the surface of the groove 109. In this particular implementation, the shield 107 is positioned with an inner surface 110 in contact with its SWP generator 101 and the shield 107 extends along the groove 109 and covers the SWP generator 101. Additionally, though not required, an outer surface 111 of the shield 107 can be flush with the exposed surface 160 so as not to disrupt flows that might be directed across the exposed surface 160 (for other purposes). In some implementations, a clamp 107C can be configured to fix the shield 107 in place as it makes contact with the SWP generator 101. The clamp 107C can be a separate piece from the shield 107, as shown in FIGS. 2A and 2B, that is attached to the exposed surface 106 with an attachment device 107A. In other implementations, the clamp 107C is integral with the shield 107 such that one end of the shield 107 is attached to the exposed surface 106 while the other end is in contact with the SWP generator 101. The SWP generator 101 makes contact with the groove surface 161 at at least one interface.

As shown in the close-up views of FIGS. 2A and 2B, and as discussed above, the electromagnetic radiation 106 can also transform material 132 that is present in the chamber 130 to produce a surface-wave plasma 120′ (at another location from the surface-wave plasma 120) that naturally spreads over one or more external surfaces of the shield 107. The surface-wave plasma 120′ can be coextensive with the surface-wave plasma 120. In this way, another self-guiding waveguide 121′ can be formed that hugs the external surfaces of the shield 107. The waveguide 121′ is the region or space between the surface-wave plasma 120′ and the surfaces of the component shield 107.

The material 132 that is converted into the surface-wave plasma can be present within the chamber 130. This means that the material 132 already exists within the chamber 130 independently of the operation of the cleaning apparatus 100. In typical implementations, the chamber 130 is initially manufactured without introducing material 132; then, material 132 is subsequently introduced prior to and/or during operation of chamber 130. The material 132 is then present in the chamber 130 during operation of the chamber 130. Thus, the material 132 does not need to be transported into the chamber 130 from outside the chamber 130 prior to operation of the cleaning apparatus 100 because the material 132 is already present in the chamber 130 for operation of the chamber 130. The material 132 can be transported into the chamber 130 via a fluid port in the vessel 131. For example, the material 132 can be supplied within the chamber 130 for other purposes during operation of the EUV light source such as to provide a fluid flow pattern or to provide a buffer over surfaces within the chamber 130.

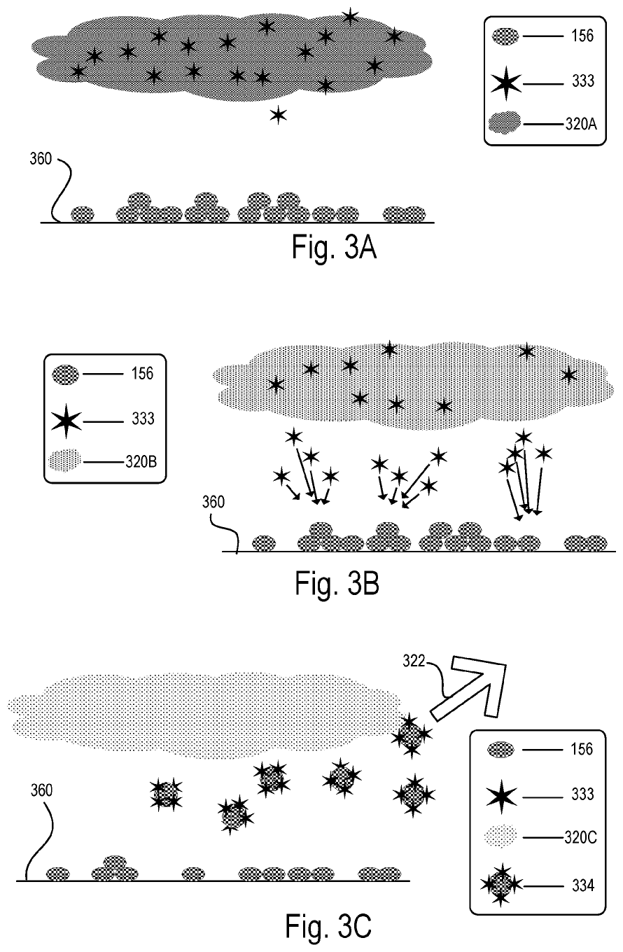

Referring to FIG. 3A, the plasma state of the material 132 is referred to as the surface-wave plasma 320A (which corresponds to the surface-wave plasma 120). The surface-wave plasma 320A includes plasma particles 333 of the material 132, and these plasma particles 333 are quite chemically reactive. For example, the plasma particles 333 can include free radicals and/or ions of the material 132. The material 132 can be in a gas state prior to being transformed by the surface-wave plasma 120. The SWP generator 101 is positioned such that the plasma particles 333 come in contact with the debris 156 on an exposed surface 360 (which can be either of the exposed surface 160 or the groove surface 161). As shown in FIG. 3B, the plasma particles 333 are attracted to the particles of the debris 156 and they travel toward the debris 156, leaving behind depleted surface-wave plasma 320B. The plasma particles 333 chemically react with the deposited particles of the debris 156 to form a new chemical 334 (as shown in FIG. 3C). As more and more of the plasma particles 333 travel toward the debris 156 to form the new chemical 334, they leave behind even more depleted surface-wave plasma 320C (as shown in FIG. 3C). The new chemical 334 is released from the exposed surface 360. For example, the new chemical 334 can be in a gaseous state, and thus becomes released from the exposed surface 360 upon formation. This new chemical 334, which is in the gaseous state, can then be pumped out of the chamber 130 by way of a removal apparatus 322.

The surface-wave plasma 120 (or 320A, 320B, 320C) is distinguished from the light-emitting plasma 136 (see FIG. 1) as follows. The light-emitting plasma 136 is produced from the interaction between the target 135 and the energy pulse 138. The light-emitting plasma 136 can be considered to be a highly-ionized plasma with electron temperatures of several tens of electron volts (eV). To be clear, the light-emitting plasma 136 produced from the target 135 is distinct from the plasma particles 333 that are in the plasma state of the material 132. The light-emitting plasma 136 is produced due to the interaction between the target 135 and the energy pulse 138 (which can be a pulse of an amplified light beam). Moreover, the light-emitting plasma 136 of the target 135 is what produces the EUV light 137. By contrast, the plasma particles 333 are created from the material 132 that is found inside the chamber 130. Neither the material 132 nor the plasma particles 333 contributes to the production of the EUV light 137. Moreover, the plasma particles 333 are not produced from any interaction of the material 132 with the energy pulse (or amplified light beam) 138.

The cleaning apparatus 100 can be configured to operate (that is remove the debris 156 from the exposed surface 160/161) even though it is exposed to molecular hydrogen, which is present in the chamber 130. Moreover, the cleaning apparatus 100 can be configured to operate without the use of or presence of oxygen; that is, oxygen is not needed or required in order for the cleaning apparatus 100 to operate and/or perform its functions.

The cleaning apparatus 100 is designed to remove the debris 156 from the exposed surface 160/161 of the component 165 without requiring the removal of the component 165 from the chamber 130. The operation of the components 165 within the chamber 130 that contribute to the production of the EUV light 137 and/or maintain the operation of the chamber 120 need not be halted in order to clean the exposed surfaces 160/161 of those components 165. Thus, the operation of the EUV light source does not need to be halted or shut down in order for the cleaning apparatus 100 to clean the surface 160/161. The cleaning apparatus 100 is able to remove most if not all of the debris 156 from the surfaces 160/161. The cleaning apparatus 100 operates to prevent the ejection of the debris 156 (such as by spitting, flaking, or dripping) from the exposed surface 160/161. Moreover, the cleaning apparatus 100 is more reliable thermally, less complex, and cheaper than previous designs that required heating of components within the chamber 130 in order to reduce the detrimental effect of the target matter 155. The cleaning apparatus 100 does not heat the component 165, and thus spitting is mitigated or avoided completely. In particular, the temperature of the chamber 130 overall is lower and the component 165 is not heated, and the overall temperature of the component 165 is lower than the melting point of the debris 156. Moreover, the consumption of the material 132 is reduced or minimized because any plasma particles 333 that do not interact with the target matter 155 in the debris 156 will reform into material 132.

In some implementations, the chamber 130 is maintained at atmospheric pressure. In other implementations, the chamber 130 is maintained at a vacuum, that is, at a pressure below atmospheric pressure. For example, the chamber 130 can be at a low pressure of between about 0.5 Torr (T) to about 1.5 T (for example, at 1 T). A particular pressure may be suitable for the most efficient generation of EUV light 137. The cleaning apparatus 100 is configured to operate in the environment of the chamber 130, and thus, if the chamber 130 is maintained at 1 T then the cleaning apparatus 100 is able to operate at that pressure.

As discussed above, the plasma particles 333 can include free radicals and/or ions of the material 132. A free radical (which can be at least one type of plasma particle 333 produced by the cleaning apparatus 100) is an atom, molecule, or ion that has an unpaired valence electron or an open electron shell, and therefore may be seen as having a dangling covalent bond. The dangling covalent bonds make free radicals highly chemically reactive, that is, a free radical can react readily with other substances. Because of their reactive nature, free radicals are used to remove a substance (such as the debris 156) from an object such as the exposed surface 160/161. The free radicals remove the debris 156 by, for example, etching, reacting with, and/or combusting the target matter 155 that forms the debris 156.

The plasma particles 333 (including the free radicals) can be created from the material 132 in any suitable manner. For example, the plasma particles 333 can be formed by breaking up the larger molecules of the material 132 that are near the exposed surface 160/161. Larger molecules are broken up by a process that puts enough energy into these larger molecules, such as ionizing radiation from the electromagnetic radiation 106. Specifically, the formation of the plasma particles 333 involves Clean Version supplying enough energy to the larger molecules of material 132 to break a bond (generally a covalent bond) between the atoms of the larger molecules.

The target 135 (see FIG. 1) can be, for example, a droplet of liquid or molten metal, a portion of a liquid stream, solid particles or clusters, solid particles contained within liquid droplets, a form of target material, or solid particles contained within a portion of a liquid stream. The target 135 can be any material that emits EUV light 137 when in the plasma state. That is, the target 135 is a substance that, when in the plasma state, has an emission line in the EUV range. For example, the target 135 can include water, tin, lithium, and/or xenon. The target 135 can be a target mixture that includes the target matter 155 as well as impurities such as non-target particles (which do not contribute to the production of the EUV light 137). As an example, the target 135 can be the element tin, which can be used as pure tin (Sn); as a tin compound such as SnBr4, SnBr2, SnH4; as a tin alloy, such as tin-gallium alloys, tin-indium alloys, tin-indium-gallium alloys; or any combination of these alloys. In the situation in which there are no impurities, the target 135 includes only the target matter 155.

In some implementations in which the target 135 includes tin (Sn), the target matter 155 that forms the debris 156 includes tin particles (for example, tin or tin oxide). One of the materials 132 present and permitted within the chamber 130 is molecular hydrogen (H₂). In this case, the plasma particles 333 (FIGS. 3A-3C) can be produced from the molecular hydrogen. The plasma particles 333 can include free radicals and ions of hydrogen. One example of a simple free radical of hydrogen is a single hydrogen element with an unpaired valence electron (H*). The chemical process that transpires due to the operation of the cleaning apparatus 100 is represented by the following chemical formula: H₂ (g)⇄2 H* (g), where g indicates that the chemical is in the gaseous state.

The generated free radicals H* of the hydrogen bond with the tin particles in the debris 156 and form the new chemical 334, which in this example, is called tin hydride (SnH4). The tin hydride is then released from the exposed surface 360. This chemical process is represented by the following chemical formula:
4 H*(g)+Sn(s)⇄SnH₄ (g), where s indicates that the chemical is in the solid state.

In this way, the coating formed from the debris 156 is etched off or removed from the exposed surface 360 at a rate of at least 10 nanometers per min and as much as 200 nm/min. The total surface area of the region of the exposed surface 360 that can be etched depends on the length of the SWP generator 101, the radius of the conducting element 102, and the current or power supplied to the conducting element 102. The total surface area extends beyond the immediate vicinity of the SWP generator 101 because the surface-wave plasma 120 travels along the exposed surface 160. As discussed above, the distance that the surface-wave plasma 120 travels depends at least on the power delivered to the conducting element 102. In one example in which the power supplied to the conducting element 102 is 2 kilowatts (kW), the distance amounts to about 30 cm. Additionally, the plasma particles 333 are created as close as possible to the exposed surface 360, or close enough that fluid flows within the chamber 130 move the plasma particles 333 quickly across the exposed surface 360 before the plasma particles 333 recombine or revert back into the material 132. This is important because hydrogen radicals H* (and other free radicals) are short lived and tend to recombine to reform molecular hydrogen. The cleaning apparatus 100 is designed to enable the plasma particles 333 to have a chance to react with the target mater 155 of the debris 156 before these plasma particles 333 have a chance to recombine with each other to reform the material 132, and this permits the cleaning of the exposed surface 360 without having to remove the component 165 from the chamber 130.

H* is not the only free radical or ion produced by the cleaning apparatus 100 from molecular hydrogen H₂. There are many other free radicals and ions that can be formed from molecular hydrogen H₂ due to the operation of the cleaning apparatus 100. These other free radicals and ions are plasma particles 333 as well. For example, Deuteron H₂+ and Triton H₃+ can also react with tin and form gaseous tin hydrides, although they are not dominant.

The inner conducting element 102 can be made of any suitable conducting material such as copper and copper alloys. The conducting element 102 is connected to terminals, and a transmitter supplies an electric current to the terminals, such that the conducting element 102 radiates the energy from the current as electromagnetic waves or radiation (for example, microwave radiation). The coaxial dielectric insulator 103 is not electrically conductive. For example, a suitable dielectric is a ceramic such as aluminum nitride, boron nitride, silicon carbide, aluminum oxide, boron carbide, and other composite ceramics. In other implementations, the dielectric can be glass, porcelain, mica, polyethylene, quartz, or sapphire.

FIG. 4 shows a cross-sectional view of an implementation 400 of the cleaning apparatus 100 of FIG. 2A taken along the 4-4 plane (with the local Y_C axis into the page). The cleaning apparatus 400 includes a shield 407 positioned next to the SWP generator 401. Because the shield 407 would not be visible in this particular view, it is shown in dashed lines in FIG. 4. The SWP generator 401 includes the inner conducting element 402, which is encased by the dielectric insulator 403 (such as alumina), which is electrically connected to ground 404. The SWP generator 401 is positioned in the groove 409 that is formed in the exposed surface 460 of the component 465. The inner conducting element 402 is coupled to a power source 408 configured to supply current to the inner conducting element 402. The current that is supplied to the inner conducting element 402 can be in the microwave range. Microwave frequencies are electromagnetic wave frequencies that lie in the range extending from around 300 megahertz (MHz) to 3 gigahertz (GHz). The power supplied to the inner conducting element 402 can be on the order of a few hundred watts (W) and the amount of power supplied to the inner conducting element 402 directly impacts the reach or extent of the surface-wave plasma 120.

While the cleaning apparatus 400 has a linear geometry (that extends generally along an axial direction, which can change), in other implementations, the cleaning apparatus can be configured as a strip or a button geometry.

In one implementation, the electric power supplied to the inner conducting element 402 is on the order of several or tens of kilowatts (kW). The inner conducting element 402 can have a diameter of less than ½ inch. The microwave frequency can be about 300 MHz to 3 GHz (and close to 900 MHz in some implementations) and the electric power supplied to the inner conducting element 402 can be about 0.1-3 kW (or on the order of a few hundred watts). The chamber 130 can be held at about pressure within a range of 1 pascal (Pa) to 140 Pa. The rate of removal of the debris 156 from the surface 160/161 can be at least 0.1 nanometers (nm)/minute (min), or about 0.2 nm/min across the entire surface 160/161.

Additionally, a control apparatus 412 can communicate with the cleaning apparatus 400 and the power source 408 to thereby control the operation of the SWP generator 401. For example, the control apparatus 412 can send a signal to the power source 408 to provide current to the inner conducting element 402. The control apparatus 412 can include one or more modules. The various modules of the control apparatus 412 can be free-standing modules in that data between the modules is not transferred from module to module. Or, one or more of the modules within the control apparatus 412 can communicate with each other. The modules within the control apparatus 412 can be co-located or separated from each other physically.

The control apparatus 412 can include memory, which can be read-only memory and/or random access memory. Storage devices suitable for tangibly embodying computer program instructions and data include all forms of non-volatile memory, including, by way of example, semiconductor memory devices, such as EPROM, EEPROM, and flash memory devices; magnetic disks such as internal hard disks and removable disks; magneto-optical disks; and CD-ROM disks. The control apparatus 412 can also include one or more input devices (such as a keyboard, touch screen, microphone, mouse, hand-held input device, etc.) and one or more output devices (such as a speaker or a monitor).

The control apparatus 412 can include one or more programmable processors, and one or more computer program products tangibly embodied in a machine-readable storage device for execution by a programmable processor. The one or more programmable processors can each execute a program of instructions to perform desired functions by operating on input data and generating appropriate output. Generally, the processor receives instructions and data from memory. Any of the foregoing may be supplemented by, or incorporated in, specially designed ASICs (application-specific integrated circuits).

Each of the modules within the control apparatus 412 can be a set of computer program products executed by one or more processors. Moreover, any of the modules can access data stored within the memory. Connections between controllers/features/modules within the control apparatus 412 and between controllers/features/modules within the control apparatus 412 and components the cleaning apparatus 100, 400 can be wired or wireless.

Referring to FIG. 5, an implementation 531 of the vessel 131 can be a part of an EUV light source 570. The EUV light source 570 of FIG. 5 is represented in a simplified schematic view and only some components of the EUV light source 570 are displayed. FIG. 5 is shown in an X-Z plane of the vessel 531, with the positive X direction aligned with an upward direction in the plane of the page, and the positive Z direction extending to the right in the plane of the page, where the Z axis is aligned with an optical axis OA of the vessel 531.

The vessel 531 defines the chamber 530 in which the region 540 is defined. The region 540 can be referred to as an irradiation site or irradiation region. As discussed above, targets 535 are provided at the region 540. To this end, the EUV light source 570 includes a target delivery system 571 that, when in operation, delivers targets 535 into an interior 575 of a flow module 576 in which the irradiation region 540 is defined. The flow module 576 is position inside the chamber 530 of the vessel 531. In this schematic view, the targets 535 travel along the-X direction from the target delivery system 571 to the irradiation region 540. At the irradiation region 540, each target 535 interacts with one or more energy pulses such as pulses of an amplified light beam 572 to produce the plasma 536 that produces the EUV light 537. For simplicity, only two rays of the EUV light 537 are depicted in FIG. 5, but it should be understood that the EUV light 537 radiates in all directions from the plasma 536.

As shown in FIG. 5, the EUV light source 570 includes an optical source 574 that, during operation, generates the energy pulses such as the pulses of the amplified light beam 572 and delivers the pulsed amplified light beam 572 from the optical source 574 into the chamber 530 and then into the interior 575 of the flow module 576 in which the irradiation region 540 is defined. The optical source 574 includes an optical system that produces the amplified light beam 572 due to a population inversion within a gain medium or mediums of the optical system. The optical system includes one or more optical amplifiers, lasers, and/or lamps for providing one or more main pulses that form the amplified light beam 572. And, in some cases, the optical system can also provide one or more pre-pulses that form a precursor amplifier light beam (not shown) that interacts with the target 535 prior to the interaction between the amplified light beam 572 and the target 535. Each optical amplifier includes a gain medium capable of optically amplifying the desired wavelength at a high gain, an excitation source, and internal optics. The optical amplifier may or may not have laser mirrors or other feedback devices that form a laser cavity. Thus, the optical system produces the amplified light beam 572 due to population inversion in the gain media of the amplifiers even if there is no laser cavity. Moreover, the optical system can produce the amplified light beam 572 that is a coherent laser beam if there is a laser cavity to provide enough feedback to the optical system. The optical amplifiers used in the optical system can include as a gain medium a gas that includes carbon dioxide (CO2) and can amplify light at a wavelength of between about 9100 and 11000 nanometers (nm), and for example, at about 10600 nm, at a gain greater than or equal to 100. Suitable amplifiers and lasers for use in the optical system include a pulsed laser device, for example, a pulsed gas-discharge CO2 laser device producing radiation at about 9300 nm or about 10600 nm, for example, with DC or RF excitation, operating at relatively high power, for example, 10 kW or higher and a high pulse repetition rate, for example, 40 kHz or more. The optical source 574 can additionally include a focusing unit that includes one or more optical elements (not shown) for focusing pulses of the light beam 572 to a focal spot or beam waist at or near the irradiation region 540 and a beam delivery system that can include or cooperate with the focusing unit.

The targets 535 include an EUV emitting target material such as, but not limited to, tin, lithium, xenon, or combinations thereof. The targets 535 can be in the form of liquid droplets, or alternatively can be solid particles or solid particles contained within liquid droplets. For example, the element tin can be presented as a target in the form of pure tin; a tin compound such as SnBr4, SnBr2, SnH4; or a tin alloy such as tin-gallium alloys, tin-indium alloys, or tin-indium-gallium alloys.

The EUV light source 570 also includes a collector 577. The collector 577 is formed with an aperture 578 that allows the amplified light beam 572 to pass and reach the irradiation region 540. The collector 577 can be a near-normal incidence collector mirror having an optical axis OA and a reflective surface 579. The reflective surface 579 can be in the form of a prolate spheroid (that is, an ellipse rotated about its major axis), such that the collector 577 has a first or primary focus (PF) within or near the irradiation region 540 and a second or intermediate focus (IF) at the exit of the flow module 576, with the optical axis OA defined as the line extended between the PF and IF. EUV light 537 that is collected by the collector 577 is provided to a device utilizing the EUV light 537. For example, the device can be a lithography exposure apparatus (as shown in FIG. 14). In order to reflect the EUV light 537, the collector 577 can be in the form of a multi-layer mirror (MLM), with the reflective surface 579 having a graded multilayer coating with alternating layers of molybdenum and silicon, and in some cases, one or more high temperature diffusion barrier layers, smoothing layers, capping layers and/or etch stop layers. Other surface shapes besides the prolate spheroid can also be used for the reflective surface 579. For example, the reflective surface 579 can alternatively be in the form of a parabola rotated about its major axis. In implementations, the reflective surface 579 can be configured to deliver a beam of the EUV light 537 having circular-shaped, a ring-shaped, or other cross section at the IF. In other implementations, the reflective surface 579 can utilize coatings and layers other than or in addition to those described above. The reflective surface 579 is configured to reflect light in the EUV wavelength range. Additionally, the reflective surface 579 can be configured to absorb, diffuse, or block light outside the EUV wavelength range.

The flow module 576 includes a liner 580 having an interior surface 581 that encloses, at least in part, the volumetric interior 575 in which, when the EUV light source 570 is in use, EUV light 537 is transmitted by the collector 577 from the PF to the IF along the optical axis OA. The liner 580 can have a conical shape such that the cross-section in the XY plane is circular or even elliptical.

A shroud 585 can be positioned in the interior 575 between the target delivery system 571 and the irradiation region 540. The shroud 585 can be considered as a solid (generally lacking an internal cavity) and rigid body that provides a semi-protected or fully-protected passageway for targets 535 as they travel from the target delivery system 571 toward the interacting region 540. The shroud 585 is configured to reduce the effect of turbulent flow within the interior 575 on the targets 535 as they travel the path to the interacting region 540. The shroud 585 is positioned to extend across the collector 577 and is so close to the interacting region 540 that the shroud 585 is susceptible to being exposed to target matter that is produced at the interacting region 540. Thus, debris from the target matter can form on surfaces of the shroud 585.

The liner 580 can include an exhaust opening 582 that opens into the interior 575 and forms a pathway out of the interior 575 for debris that is created within the interior 575. Such debris that is ejected or directed out of the interior 575 through the exhaust opening 582 can be collected by an external debris handling apparatus. The interior 575 can accommodate gas flows that can be used as a buffer gas for debris and/or vapor emanating from the irradiation region 540. In some implementations, hydrogen (H₂) is used as a hydrogen gas flow within the interior 575 since hydrogen is relatively transparent to EUV radiation having a wavelength of about 13.5 nanometers (nm). Hydrogen gas can be introduced into the interior 575 to slow down and/or guide energetic debris (such as ions, atoms, and clusters) of target material created by irradiation of the targets 535 at the irradiation region 540 and by the resulting plasma 536. The debris (which is highly energetic) is slowed down (or de-energized) by collisions with the gas molecules (the H₂ molecules) in the flow. This gas flow can be directed to prevent debris produced at the irradiation region 540 from reaching specific surfaces within the flow module 576 (for example, the reflective surface 579 of the collector 577, the interior surface 581 of the liner 580, or surfaces of the shroud 585). Thus, this gas flow can reduce damage to the collector 577 otherwise caused by vapor deposition, implantation, and deposition of sputtered target material.

When targets 535 that are tin or tin-containing are used, the use of hydrogen gas for gas flow with tin targets 535 can result in another potential source of contamination in the interior 575 of the flow module 576. In particular, molten tin can be ejected or spit from surfaces in the interior 575 that are coated or subject to coating with the molten tin when hydrogen bubbles form and grow in or under the molten tin and then burst. One way to prevent tin spitting is to prevent molten target material from accumulating on a surface within the interior 575 of the flow module 576 by keeping the temperature of the surface below or well below the melting point of the target material. The melting point of tin is about 232° C. For example, some surfaces of objects or portions of the interior 575 can be maintained at a temperature below 232° C., or in a temperature in the range of about 50° C. to about 110° C. Any tin that deposits on a surface maintained at that temperature is kept in solid form and prevents or resists spitting.

The deposition of debris onto cold surfaces within the interior 575 can shorten the length of service intervals of the EUV light source 570. Growth of such deposits on cold surfaces and accumulation of liquid tin on surfaces can be reduced by the use of gas flows inside the interior 575. Different gas flows can be used. For example, one or more gas flows can be directed along the reflective surface 579 of the collector 577. As another example, one or more gas flows can be directed through apertures generally perpendicular to a surface to be protected within the interior 575. Gas flows can be directed through one or more walls of the chamber liner 580. As a further example, protective gas flows can be parallel to, or have a component of flow directed parallel to, the surface to be protected (such as in regions near the intermediate focus IF). As a further example, a gas flow (referred to as a dynamic gas lock) can be used to prevent material from leaving the EUV light source 570 in the region of the intermediate focus IF. A dynamic gas lock can produce a gas flow from the region of the intermediate focus IF toward the irradiation region 540. In general, a stable guided flow that flows away from the collector 577 can be formed from a combination of one or more of these flows. This guided flow helps contain and carry away the debris, which includes vapor, ions, and micro and nano-particles, and is generated from the targets 535 during the production of plasma 536, from the collector 577, the shroud 585, and the interior surface 581 of the liner 580. Other flows can be formed.

Low pressures are used within the interior 575, and pressure differentials at the exhaust opening 582 are not large. Nevertheless, a small pressure differential at the exhaust opening 582 is produced by vacuum pumping the exhaust opening 582 (by way of an external exhaust pump that is in fluid communication with the exhaust opening 582). The stable guided flow of the debris entrained and contained in the flow is thereby directed into the exhaust opening 582 and out of the interior 575, thus substantially reducing the amount of debris contacting surfaces within the interior 575.

The exhaust opening 582 is configured to remove the released chemical 334 (FIG. 3C) from the interior 575 as well as other gaseous byproducts that can form within the interior 575 during production of the EUV light 536. As discussed above, the released chemical 334 is formed from the interaction of the plasma particles 333 (produced from the material 132) with the target matter 155 that has deposited on the exposed surface 360 of the component. A removal apparatus 522 such as a pump fluidly communicating with the exhaust opening 582 can therefore remove the released chemical 334 from the interior 575. Once the new chemical 334 is formed, it is released from the exposed surface 360 of the component. And, because the new chemical 334 is in a gaseous state, it Clean Version can be sucked through the exhaust opening 582 and to the removal apparatus 522, which removes the new chemical 334 from the interior 575.

The cleaning apparatus 100 can be positioned in the interior 575 at any surface that is in the line of sight of the optical axis OA or is exposed to the plasma 536. A plurality of cleaning apparatuses 100 can be associated with respective surfaces throughout the interior 575 of the liner 580. Possible and exemplary (but not limiting) locations for the cleaning apparatus 100 are marked by icons 584 shown in FIG. 5. For example, the cleaning apparatus 100 can be positioned next to any element that includes a surface that could potentially interact with the target matter 155 and thus potentially become coated with the debris 156 during operation of the EUV light source 570. Thus, one or more cleaning apparatuses 100 can be positioned next to the surface 579 of the collector 577; next to any interior surface 581 of the liner 580; next to the target delivery system 571; and/or next to the shroud 585. While the cleaning apparatuses 100 are depicted by icons 584 in the plane of the page in FIG. 5, it should be noted that they could extend any direction along the plane of the page or any distance into or out of the plane of the page.

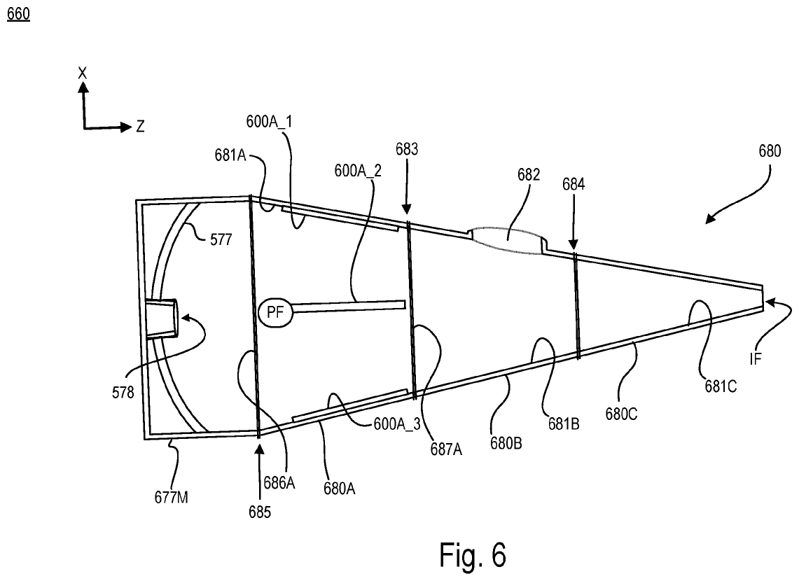

While the liner 580 is shown as a single unitary piece, it can be made up of a plurality of pieces. An implementation 680 of a multi-piece conical liner is shown in FIG. 6. The multi-piece liner 680 can include a base sub-liner 680A connecting to a mount 677M that holds the collector 577 and defining the primary focus PF, a middle sub-liner 680B in which the exhaust opening 682 is defined, and a secondary sub-liner 680C that extends toward the intermediate focus IF. Each of the sub-liners 680A, 680B, 680C are conical in shape. The base sub-liner 680A and the middle sub-liner 680B are connected at a first interface 683 and the middle sub-liner 680B and the secondary sub-liner 680C are connected at a second interface 684. The base sub-liner 680A connects to the collector mount 677M at a third interface 685. The base sub-liner 680A defines an interior surface 681A, the middle sub-liner 680B defines an interior surface 681B, and the secondary sub-liner 680C defines an interior surface 681C.

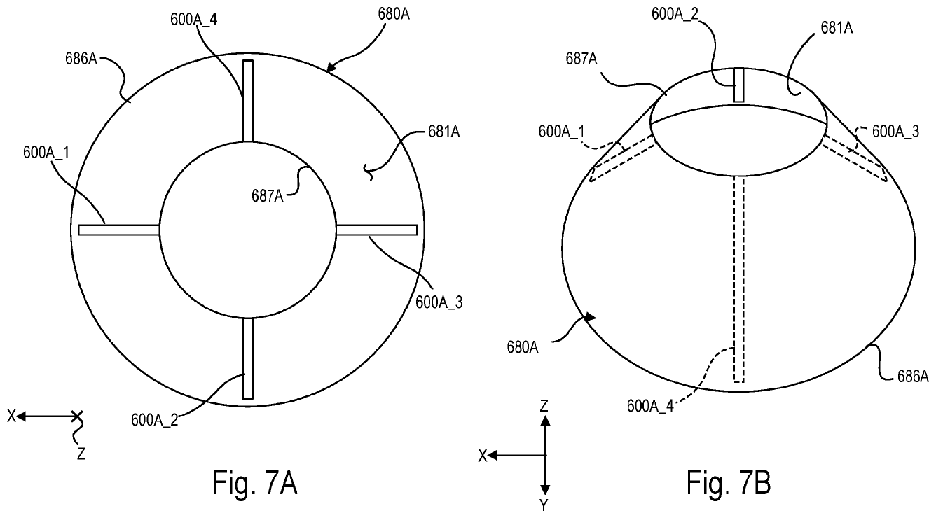

In some implementations, a plurality of cleaning apparatuses 600A_i, where i is a set of numbers from 1 to an integer greater than 1, are positioned at the interior surface 681A of the base sub-liner 680A. Cleaning apparatuses 600A_1, 600A_2, and 600A_3 are visible in the view of FIG. 6. The base sub-liner 680A is shown in two additional views in FIGS. 7A and 7B, and all four of the cleaning apparatuses 600A_1, 600A_2, 600A_3, 600A_4 are visible in FIGS. 7A and 7B. The base sub-liner 680A is a conical shape and includes a circular end 686A that is at the third interface 685 when connected to the collector mount 677M and a circular end 687A that is at the first interface 683 when connected with the middle sub-liner 680B. The cleaning apparatuses 600A_1, 600A_2, 600A_3, 600A 4 extend along the interior surface 681A and are positioned 90 degrees apart from each other. Thus, each cleaning apparatus 600A_1, 600A_2, 600A_3, 600A_4 is associated with a distinct portion of the exposed interior surface 681A. Each cleaning apparatus 600A_1, 600A_2, 600A_3, 600A_4 includes a component that extends along an axial path that aligns with the Z axis. Generally, each cleaning apparatus 600A_1, 600A_2, 600A_3, 600A_4 extends between the circular end 686A and the circular end 687A.

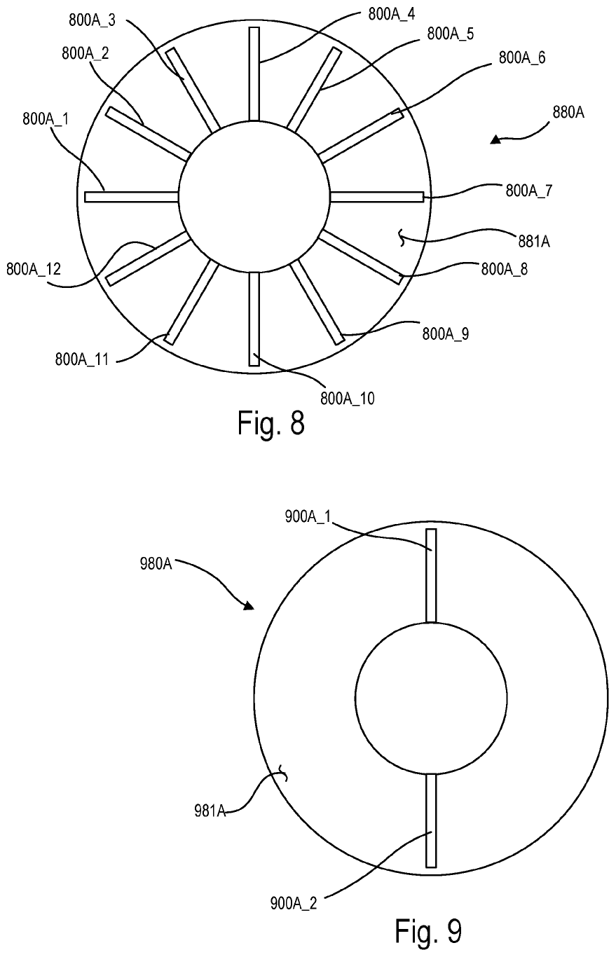

As shown in FIG. 8, it is possible to configure twelve cleaning apparatuses 800A_1, 800A_2, . . . 800A_12 at and around the interior surface 881A of the base sub-liner 880A. As shown in FIG. 9, in other implementations, just two cleaning apparatuses 900A_1, 900A_2 are mounted at the interior surface 981A of the base sub-liner 980A. Additionally, one or more cleaning apparatuses 100 can be used to clean the middle sub-liner 680B and/or the secondary sub-liner 680C (FIG. 6). There is no upper or lower limit on the number of cleaning apparatuses 100 that can be configured with the base sub-liner 680A or any single component 165. For example, there could be at least two and up to 26 cleaning apparatuses 800A configured around the interior surface 881A of the base sub-liner 880A. There could be more than 26 cleaning apparatuses 800A configured around the interior surface 881A of the base sub-liner 880A, depending on the size of each cleaning apparatus 800A relative to the surface area of the interior surface 881A.

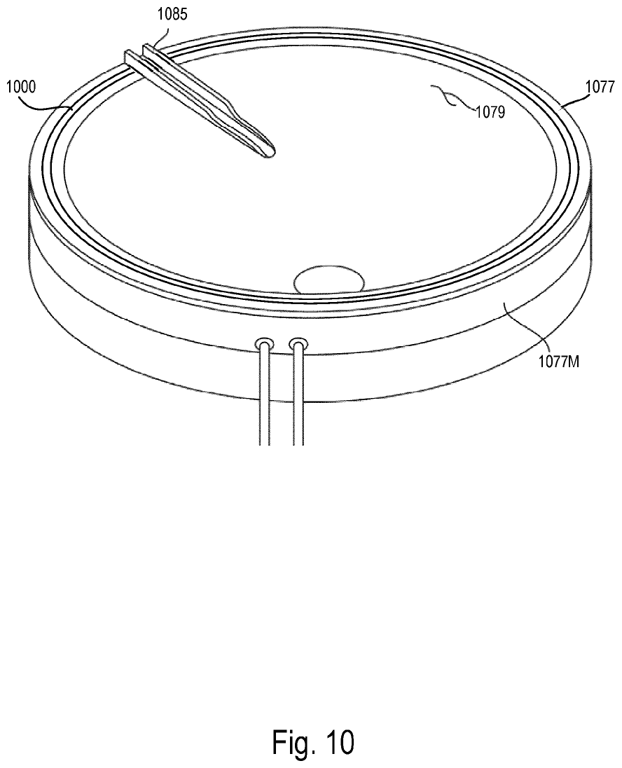

Referring to FIG. 10, an implementation 1077 of the collector 577 is shown mounted to a mount 1077M and an implementation 1085 of the shroud 585 is shown. One or more cleaning apparatuses 1000 can be used to clean the surface 1079 of the collector 1077. The cleaning apparatus 1000 can be designed as a ring positioned at the edge around the circumference of the surface 1079 of the collector 1077. In other implementations, the cleaning apparatus 1000 can be designed as a pair of semi-circular shapes or even a plurality of shorter arc shapes at the edge around the circumference of the surface 1079 of the collector 1077 and such shapes can be manufactured separately and then joined together at the surface 1079.

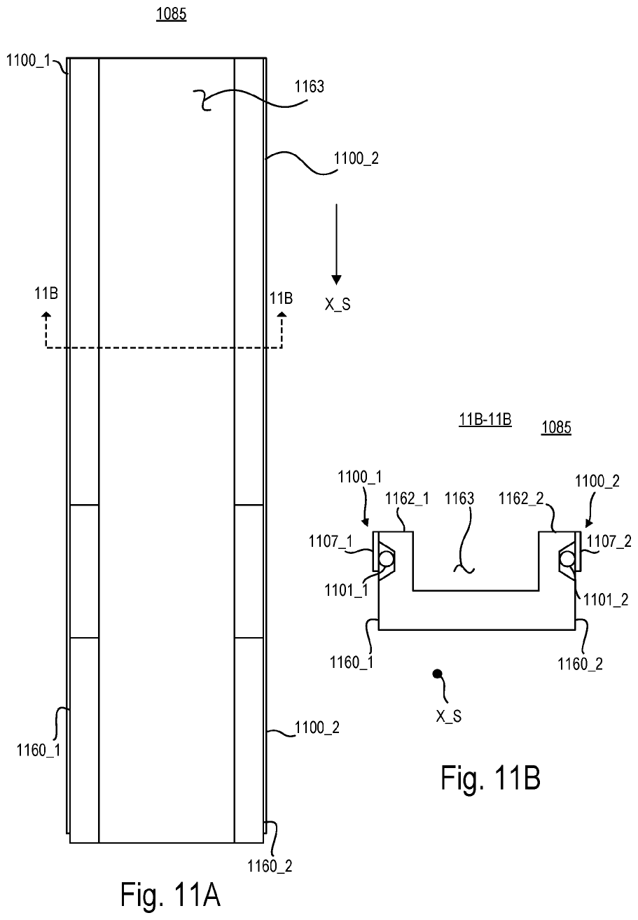

Additionally, or alternatively, as also shown in FIGS. 11A and 11B, one or more cleaning apparatuses such as cleaning apparatuses 1100_1, 1100_2 can be used to clean respective outer surfaces 1160_1, 1160_2 of respective side walls 1162_1, 1162_2 of the U-shaped shroud 1085. The side walls 1162_1, 1162_2 generally extend along a local X_S axis of the shroud 1085 to thereby define and interior 1163 through which the targets 535 travel from the target delivery system 571 to the irradiation region 540 (FIG. 5). In this implementation, the cleaning apparatuses 1100_1, 1100_2 are positioned at the top of respective sides of the shroud 1085. The cleaning apparatuses 1100_1, 1100_2 can extend along the entire length of the walls 1162_1, 1162_2 along the local X_S axis. Each cleaning apparatus 1100_1, 1100_2 includes a shield 1107_1, 1107_2 configured to protect the underlying respective SWP generator 1101_1, 1101_2.

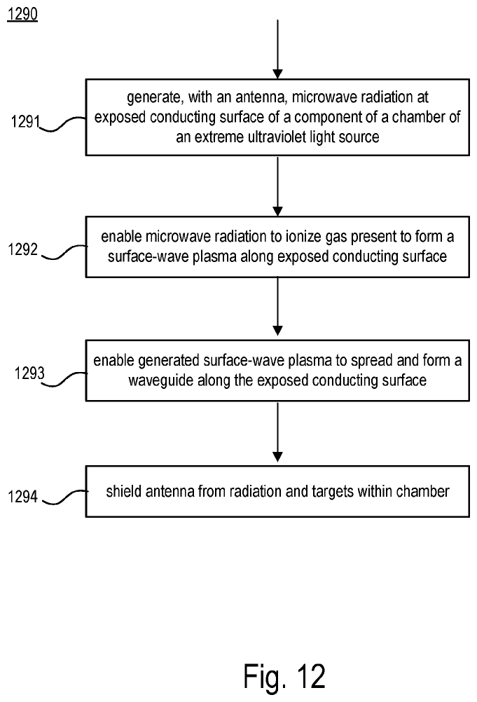

Referring to FIG. 12, and with additional reference to FIGS. 1, 2A, 2B, and 3A-3C, a procedure 1290 is performed for cleaning the exposed surface 160/161 of the component 165 of the chamber 130. The procedure 1290 enables the removal of target debris 156 from the exposed surface 160/161 without separating or removing the component 165 from the chamber 130. The procedure 1290 includes generating microwave radiation 106 from an antenna (such as the surface-wave plasma generator 101) that contacts the exposed conductive surface (1291). The procedure 1290 includes enabling the microwave radiation 106 to ionize gas (or material 132) present at the exposed conductive surface 160/161 to form a surface-wave plasma 120 at the exposed conductive surface 160/161 (1292). The procedure 1290 includes enabling the generated surface-wave plasma 120 to spread along the exposed conductive surface 160/161 such that a waveguide 121 is generated between the plasma 120 and the exposed conductive surface 160/161 (1293). The procedure 1290 also includes shielding the antenna 101 from radiation and targets within the chamber 130 and also dissipating heat away from the antenna 101 (1294).

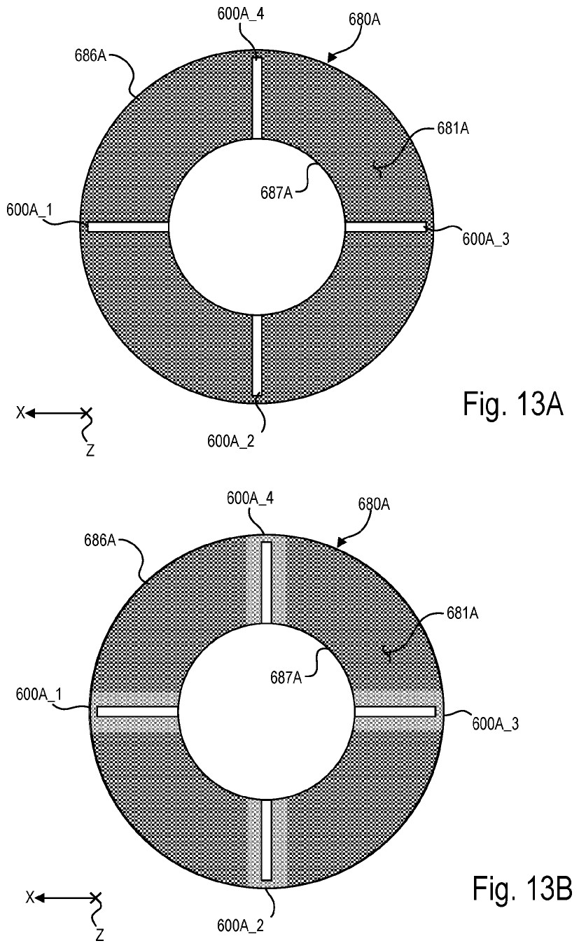

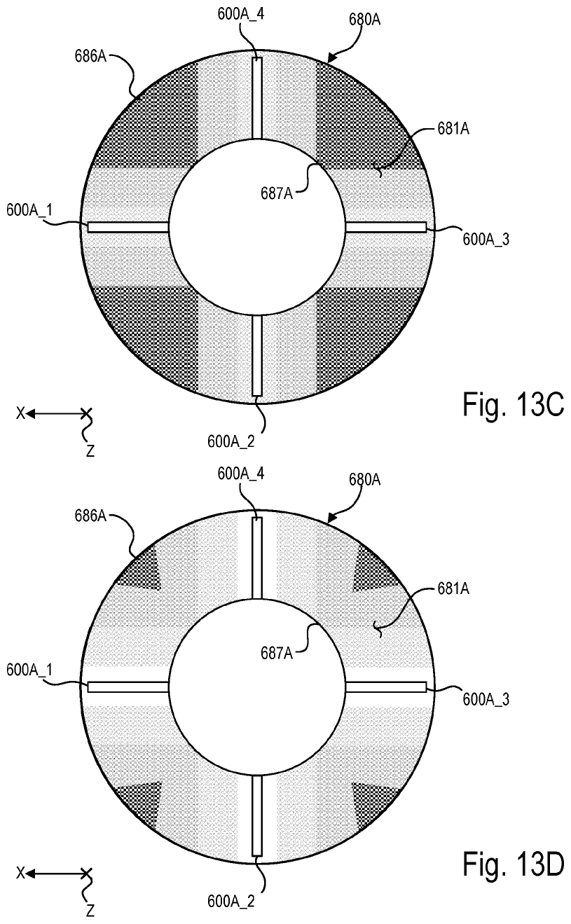

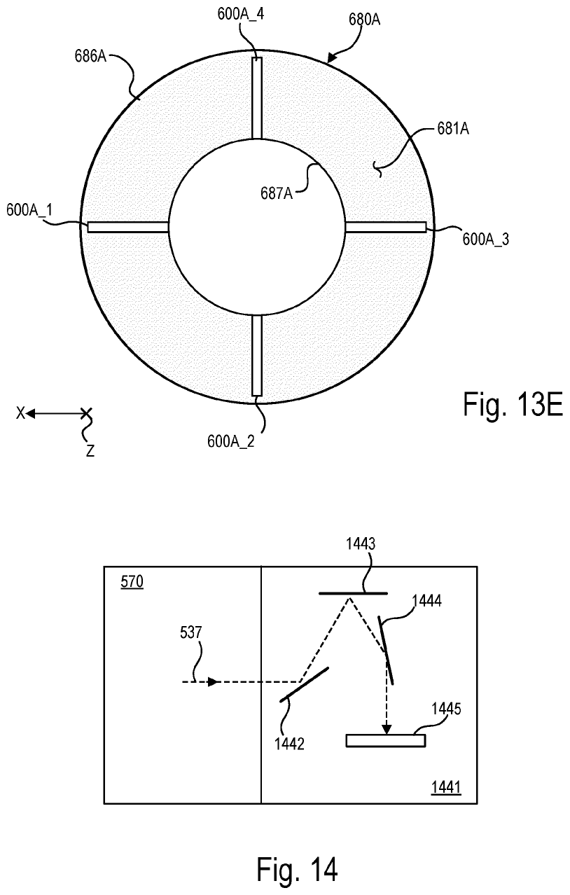

Referring to FIGS. 13A-13E, the base sub-liner 680A is shown as it is being cleaned with the cleaning apparatuses 600A_1, 600A_2, 600A_3, 600A_4 shown in FIGS. 7A and 7B. FIG. 13A is a view of the base sub-liner 680A at a time tA; FIG. 13B is a view of the base sub-liner 680A at a time tB; FIG. 13C is a view of the base sub-liner 680A at a time tC; FIG. 13D is a view of the base sub-liner 680A at a time tD; and FIG. 13E is a view of the base sub-liner 680A at a time tE. Time tE is later than time tD, which is later than time tC, which is later than time tB, which is later than time tA. The cleaning apparatuses 600A_1, 600A_2, 600A_3, 600A_4 are turned on after FIG. 13A and before FIG. 13B and by the time tE (FIG. 13E), the surface 681A has been effectively cleaned. To be clear, the lighter the shading depicted in FIGS. 13A-13E the cleaner the surface.

Referring to FIG. 14, an implementation of a lithography exposure apparatus 1441 that receives the EUV light 537 produced by the EUV light source 570 (FIG. 5). The lithography exposure apparatus 1441 reflects the EUV light 537 in one or more illumination mirrors 1442 so as to illuminate a reflective pattern or reticle 1443. EUV light reflected from the pattern or reticle 1443 is further reflected and reduced by one or more reducing mirrors 1444 and irradiated on a substrate or wafer 1445 (or on one or more photosensitive layers on the substrate or wafer 1445, not shown) to produce patterned structures in or on the substrate or wafer 1445. In some embodiments, an inspection apparatus receives the EUV light 537 produced by the EUV light source to detect defects and measure critical dimensions with high precision.

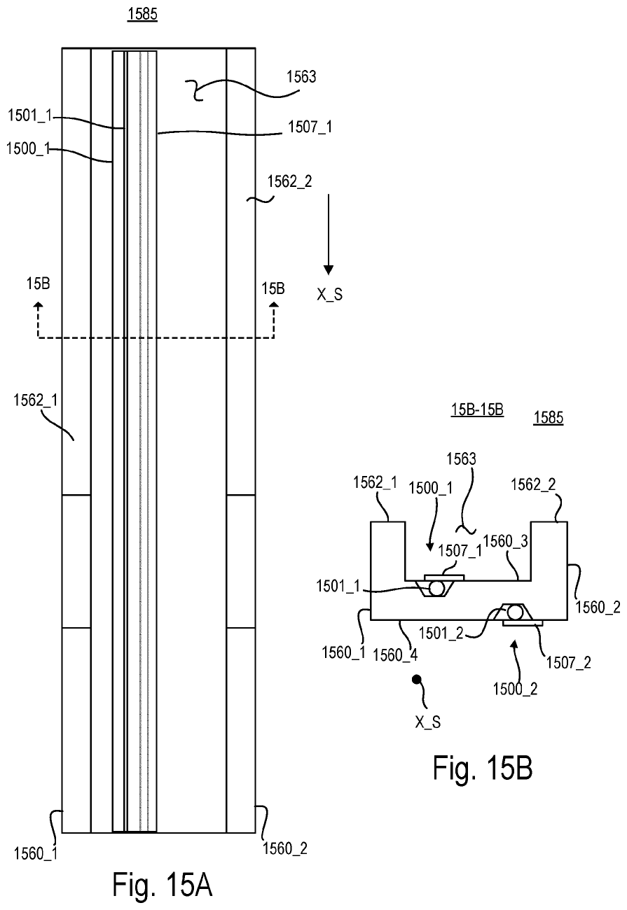

Referring to FIG. 15A and 15B, the one or more cleaning apparatuses such as the cleaning apparatuses 1100_1 and 1100_2 discussed above with reference to the U-shaped shroud 1085 can be positioned at other locations on a shroud 1585. For example, one or more cleaning apparatuses 1500_1 can be positioned relative to a surface 1560_3 defined between respective side walls 1562_1, 1562_2 of the U-shaped shroud 1585 and one or more cleaning apparatuses 1500_2 can be positioned relative to an outer surface 1560 4 that extends between outer surfaces 1560_1, 1560_2. Like the shroud 1085 of FIGS. 11A and 11B, the side walls 1562_1, 1562_2 generally extend along a local X_S axis of the shroud 1585 to thereby define and interior 1563 through which the targets 535 travel from the target delivery system 571 to the irradiation region 540 (FIG. 5). In this implementation, the cleaning apparatuses 1500_1, 1500_2 are positioned at the top and bottom of the base of the shroud 1585. The cleaning apparatuses 1500_1, 1500_2 can extend along the entire length of the base along the local X_S axis. Each cleaning apparatus 1500_1, 1500_2 includes a shield 1507 1, 1507 2 configured to protect the underlying respective SWP generator 1501_1, 1501_2.

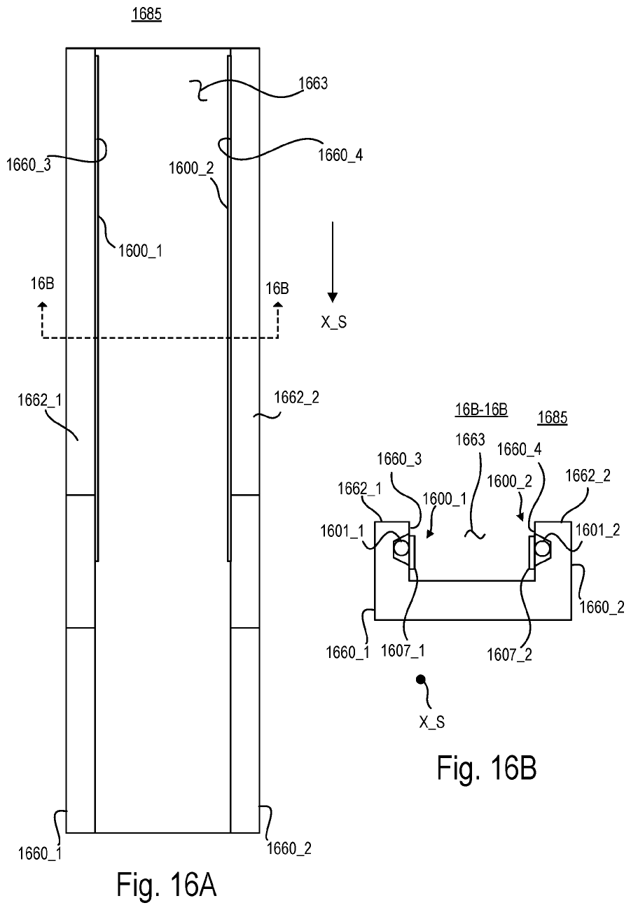

Referring to FIG. 16A and 16B, the one or more cleaning apparatuses such as the cleaning apparatuses 1100_1 and 1100_2 discussed above with reference to the U-shaped shroud 1085 can be positioned at still other locations on a shroud 1685. For example, one or more cleaning apparatuses 1600_1, 1600_2 can be positioned relative to surfaces 1660_3, 1660_4 defined at respective side walls 1662_1, 1662_2 of the U-shaped shroud 1685, the outer surfaces 1660_3, 1660_4 positioned opposite to outer surfaces 1660_1, 1660_2, respectively. Like the shroud 1085 of FIGS. 11A and 11B, the side walls 1662_1, 1662_2 generally extend along a local X_S axis of the shroud 1685 to thereby define and interior 1663 through which the targets 535 travel from the target delivery system 571 to the irradiation region 540 (FIG. 5). In this implementation, the cleaning apparatuses 1600_1, 1600_2 are positioned to face the interior 1663. The cleaning apparatuses 1600_1, 1600_2 can extend along a portion or along the entire length of the interior 1663 along the local X_S axis. Each cleaning apparatus 1600_1, 1600_2 includes a shield 1607_1, 1607_2 configured to protect the underlying respective SWP generator 1601_1, 1601_2.

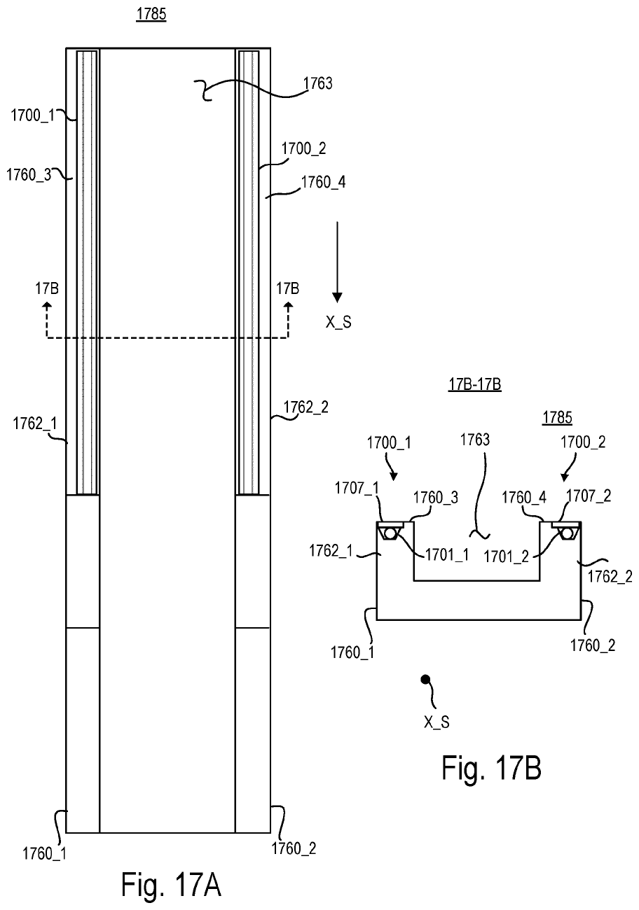

Referring to FIG. 17A and 17B, the one or more cleaning apparatuses such as the cleaning apparatuses 1100_1 and 1100_2 discussed above with reference to the U-shaped shroud 1085 can be positioned at still other locations on a shroud 1785. For example, one or more cleaning apparatuses 1700 1, 1700_2 can be positioned relative to respective outer end surfaces 1760_3, 1760_4 defined at ends of the respective side walls 1762_1, 1762_2 of the U-shaped shroud 1785. Like the shroud 1085 of FIGS. 11A and 11B, the side walls 1762_1, 1762_2 generally extend along a local X_S axis of the shroud 1785 to thereby define and interior 1763 through which the targets 535 travel from the target delivery system 571 to the irradiation region 540 (FIG. 5). In this implementation, the cleaning apparatuses 1700_1, 1700_2 are positioned at the ends of the respective side walls 1762_1, 1762_2. The cleaning apparatuses 1700_1, 1700_2 can extend along a portion of or the entire length of the interior 1763 along the local X_S axis. Each cleaning apparatus 1700_1, 1700_2 includes a shield 1707_1, 1707_2 configured to protect the underlying respective SWP generator 1701_1, 1701_2.

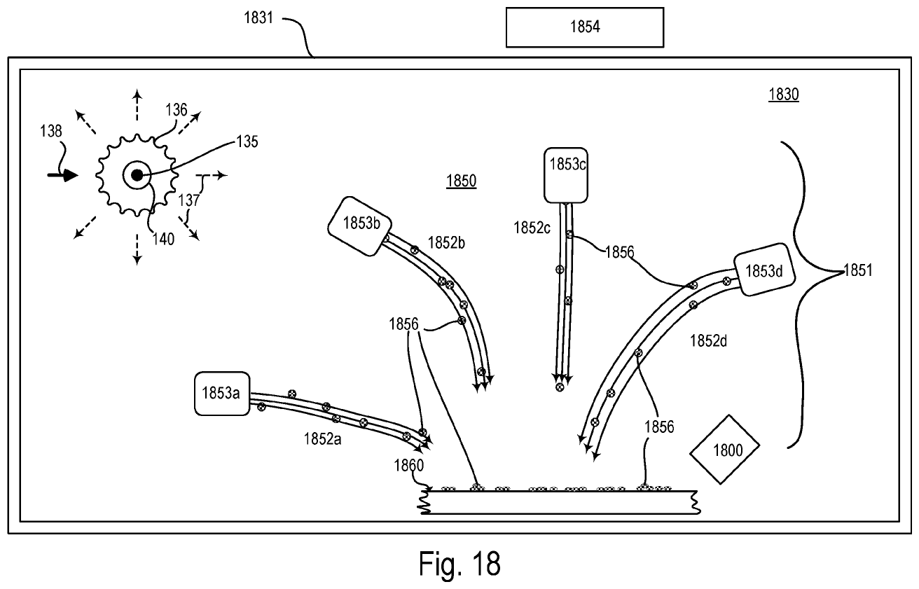

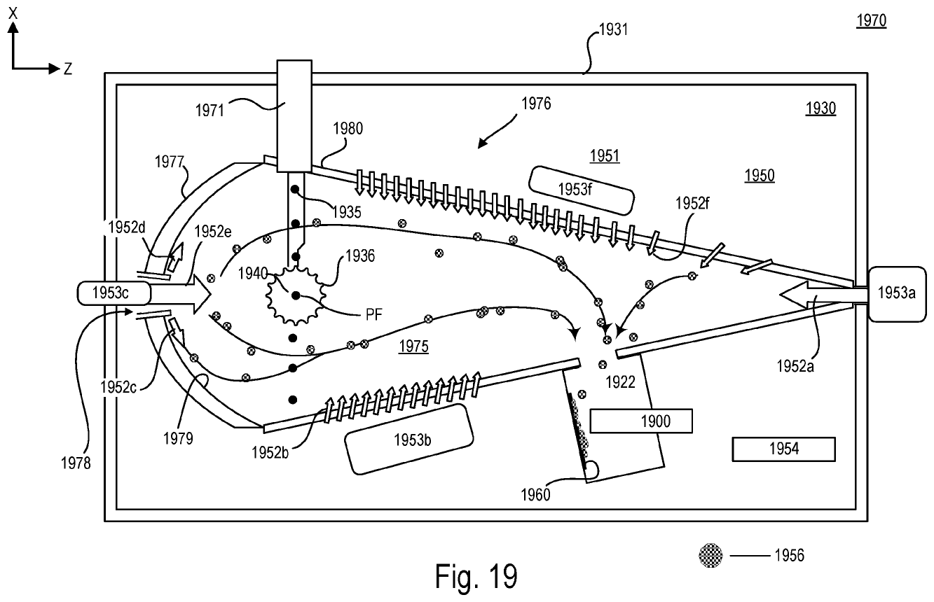

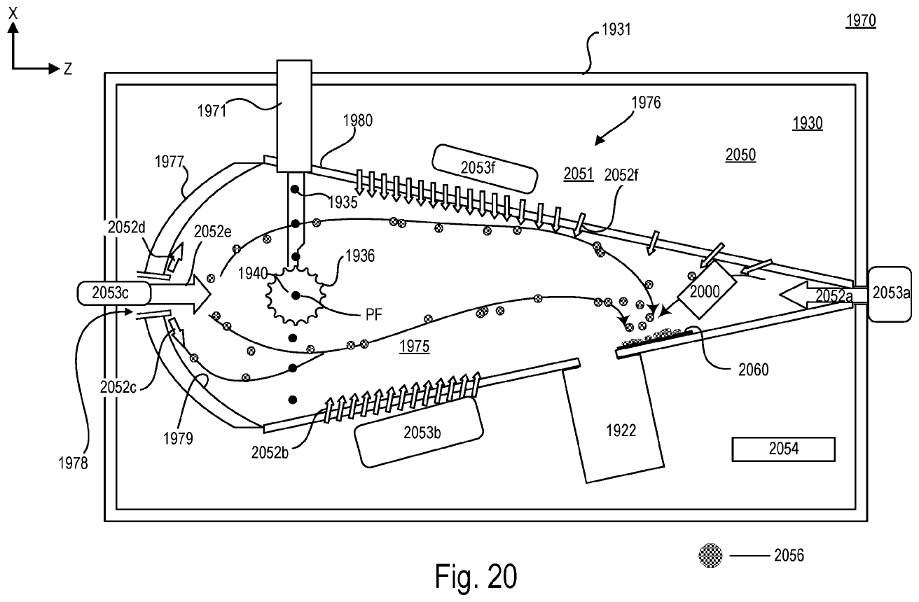

Referring to FIG. 18, in other implementations, an apparatus 1850 includes: a debris flow apparatus 1851 and a cleaning apparatus 1800. The debris flow apparatus 1851 is configured to direct and thereby deposit debris 1856 (such as target debris) to one or more surfaces 1860 in or adjacent to a chamber 1830 of an EUV light source. The cleaning apparatus 1800 is configured to remove the debris 1856 from the one or more surfaces 1860. The use of the debris flow apparatus 1851 to direct the debris 1856 to a pre-determined location or locations (at the one or more surfaces 1860) enables a more efficient removal of the debris 1856 at the one or more surfaces 1860. In particular, in other approaches, without the use of the flow apparatus 1851, the debris 1856 can be deposited on many other relevant surfaces within the chamber 1830. Thus, a cleaning apparatus 1800 is required to be positioned at each of these many different locations within the chamber 1830 in order to adequately clean these relevant surfaces within the chamber 1830. Some of these relevant locations within the chamber 1830 can have geometries that make it difficult to adequately clean with the cleaning apparatus 1800. By contrast, the apparatus 1850 configures the cleaning apparatus 1800 at or adjacent to the location of the one or more surfaces 1860. And, the location of the one or more surfaces 1860 can be selected to enable a more efficient use of the cleaning apparatus 1800. For example, the location of the one or more surfaces 1860 can be remote from the region 140 at which the targets 135 are provided within the chamber 130. Examples of locations of the one or more surfaces 1860 are discussed below with reference to FIGS. 19 and 20 after a general discussion relating to the apparatus 1850.

The cleaning apparatus 1800 includes an active etching device configured to etch the debris 1856 that has been deposited on the one or more surfaces 1860. The active etching device is any device that uses etching to remove material from the surface 1860. In some implementations, the active etching device of the cleaning apparatus 1800 is designed like the cleaning apparatus 100 of FIGS. 1-17B, and therefore includes a surface-wave plasma (SWP) generator. In other implementations, the active etching device of the cleaning apparatus 1800 includes an inductively-coupled plasma (ICP) generator, a radio-frequency (RF) discharge plasma generator, an indirect plasma generator, a microwave discharge generator, a direct current discharge generator, an electron cyclotron resonance plasma generator, and a direct plasma generator.

The debris flow apparatus 1851 includes one or more gas flows 1852a, 1852b, 1852c, 1852d that are directed toward the one or more surfaces 1860. Each gas flow 1852a, 1852b, 1852c, 1852d is in fluid communication with a respective gas supply or supplies 1853a, 1853b, 1853c, 1853d. The gas supply or supplies 1853a, 1853b, 1853c, 1853d can be positioned external to the chamber 1830 and also in fluid communication with the chamber 1830 by way of openings in the vessel 1831 in which the chamber 1830 is defined. Additionally, the debris flow apparatus 1851 includes a flow controller 1854 in communication with each of the gas supplies 1853a, 1853b, 1853c, 1853d. The flow controller 1854 is configured to adjust the one or more gas flows 1852a, 1852b, 1852c, 1852d.

While FIG. 18 shows a single surface 1860 it is possible for there to be a plurality of surfaces 1860 to which the debris 1856 is directed by way of the gas flows 1852a, 1852b, 1852c, 1852d. Moreover, while FIG. 18 shows four gas supplies 1853a, 1853b, 1853c, 1853d and four gas flows 1852a, 1852b, 1852c, 1852d, in other implementations, there can be fewer than four or more than four gas supplies and gas flows.

Referring to FIG. 19, an implementation of an apparatus 1950 is designed with a vessel 1931 of an EUV light source 1970. The vessel 1931 defines a chamber 1930 in which an irradiation region 1940 is defined. Targets 1935 are provided at the region 1940. To this end, the EUV light source 1970 includes a target delivery system 1971 that, when in operation, delivers targets 1935 into an interior 1975 of a flow module 1976 in which the irradiation region 1940 is defined. The flow module 1976 is position inside the chamber 1930 of the vessel 1931. The apparatus 1950 includes: a debris flow apparatus 1951 and a cleaning apparatus 1900 positioned relative to a surface 1960. The debris flow apparatus 1951 is positioned to control the flow of the debris 1956 in the interior 1975 of a conical liner 1980. The debris flow apparatus 1951 includes a plurality of gas flows 1952a, 1952b, 1952c, 1952d, 1952e, 1952f. In some implementations, depending on the status of the EUV light production (FIG. 5), not all of the gas flows shown need to be used at any one moment. In other implementations, a fewer number or a greater number of gas flows can be utilized. Moreover, the gas flows 1952b and 1952f can each include a plurality of gas flows, as shown. Each gas flow 1952a, 1952b, 1952c, 1952d, 1952e, 1952f is associated with a gas supply 1953a, 1953b, 1953c, 1953f, which are in communication with a flow controller 1954.

As shown in FIG. 19, the one or more surfaces 1960 to which the debris 1956 is directed by the debris flow apparatus 1951 include a location within the exhaust opening or within the removal apparatus 1922.

The gas flows 1952a, 1952b, 1952c, 1952d, 1952e, 1952f can correspond to flows of hydrogen (H₂) gas at pressures in the range of about 50 to about 300 Pa. In particular, hydrogen (H₂) is relatively transparent to EUV radiation having a wavelength of about 13.5 nm. However, there can be other materials that are suitable for the gas flows. In operation, the H₂ gas is introduced into the interior 1975 to slow down and guide energetic debris (ions, atoms, vapor, and clusters) 1956 of target material created by the irradiation of the targets 1935 and by the resulting plasma 537 (FIG. 5). The debris 1956 is slowed down and then guided by collisions with the gas molecules of these gas flows.

For example, the flow 1952e is at the center aperture of a collector 1977 and can serve to reduce direct damage to the collector 1977 caused by vapor deposition, implantation, and deposition of sputtered target material (debris 1956) by directing the debris 1956 away from the collector 1977 and toward the surface 1960. As another example, the gas flow 1952c is directed along a surface 1979 of the collector 1977 (from outlets not shown). As a further example, the gas flows 1952b, 1953f are passed through multiple apertures of the liner 1980. The gas flow 1952a in the region near the intermediate focus IF (FIG. 5) is a protective gas flow that is directed toward the irradiation region 1940 to prevent the debris 1956 from escaping from the interior 1930 and entering a downstream device.

The combination of these gas flows 1952a, 1952b, 1952c, 1952d, 1952e, 1952f can provide a stable guided flow flowing away from the collector 1977 and from the irradiation region 1940 as well as away from the intermediate focus IF (FIG. 5) and toward the surface 1960. The cleaning apparatus 1900 is configured to actively etch the debris 1956 deposited on the surface 1960.

Referring to FIG. 20, an implementation of an apparatus 2050 is designed with the vessel 1931 of the EUV light source 1970 in a similar fashion as the apparatus 1950. The apparatus 2050 includes: a debris flow apparatus 2051 and a cleaning apparatus 2000 positioned relative to a surface 2060. The debris flow apparatus 2051 is positioned to control the flow of the debris 2056 in the interior 1975 of the conical liner 1980. The debris flow apparatus 2051 includes a plurality of gas flows 2052a, 2052b, 2052c, 2052d, 2052e, 2052f. In some implementations, depending on the status of the EUV light production, not all of the gas flows shown need to be used at any one moment. In other implementations, a fewer number or a greater number of gas flows can be utilized. Moreover, the gas flows 2052b and 2052f can each include a plurality of gas flows, as shown. Each gas flow 2052a, 2052b, 2052c, 2052d, 2052e, 2052f is associated with a gas supply 2053a, 2053b, 2053c, 2053f, and the gas supplies 2053a, 2053b, 2053c, 2053f are in communication with a flow controller 2054.

As shown in FIG. 20, the one or more surfaces 2060 to which the debris 2056 is directed by the debris flow apparatus 2051 include a location within the conical liner 1980, the location being positioned between the collector mirror 1977 and the intermediate focus IF (FIG. 5) of the collector mirror 1977. The location of the surface 2060 within the conical liner 1980 can be adjacent the exhaust opening fluidly communicating with the removal apparatus 1922, as shown in FIG. 20.

Other implementations are within the scope of the following claims.

The implementations can be further described using the following clauses.
1. An apparatus comprising:
   a component of a chamber of an extreme ultraviolet (EUV) light source, the component including at least one exposed surface; and
   a cleaning apparatus configured to remove target debris from the exposed surface of the component without separating the component from the chamber, the cleaning apparatus comprising:
   one or more surface-wave plasma (SWP) generators, with each SWP generator being disposed in a groove formed in the exposed surface of the component; and
   for each SWP generator, a shield placed between an interior of the chamber and the SWP generator; wherein the shield, the SWP generator, and the exposed surface define at least one open channel between the SWP generator and the interior of the chamber, the open channel extending across the groove.
2. The apparatus of clause 1, wherein the SWP generator comprises an inner electrical conductor extending along an axial direction of the groove of the component and a dielectric insulator surrounding the inner electrical conductor and extending along the axial direction, the dielectric insulator in contact with a groove surface and the shield in contact with the dielectric insulator.
3. The apparatus of clause 1, wherein the axial direction of the inner electrical conductor is parallel to the exposed surface.
4. The apparatus of clause 1, wherein the shield includes a heat conductive and rigid material that is non-reactive with a target within the chamber that produces EUV light.
5. The apparatus of clause 1, wherein the shield comprises aluminum, aluminum oxide, steel, iron, copper, stainless steel, an alloy of nickel including chromium and iron, molybdenum, or a carbon-based steel alloy.

6. The apparatus of clause 1, wherein each respective shield is positioned with an inner surface in contact with its SWP generator and an outer surface flush with the exposed surface.
7. The apparatus of clause 6, wherein each SWP generator makes contact with a groove surface at at least one interface.
8. The apparatus of clause 1, wherein, in operation, each SWP generator radiates electromagnetic energy, which transforms a material that is present in the chamber from a first state into a plasma state that includes plasma particles, and the plasma particles and the exposed surface of the component form a waveguide for the propagation of the electromagnetic energy, the waveguide at least partly in the open channel.
9. The apparatus of clause 8, wherein, in operation, part of the guided electromagnetic energy continues to transform material present in the chamber at another location along the waveguide into the plasma state that includes plasma particles.
10. The apparatus of clause 8, wherein, in operation, at least some of the plasma particles are free radicals, free electrons, and/or ions of the material, such that the plasma particles come in contact with the debris on the exposed surface of the component.

11. The apparatus of clause 8, wherein each SWP generator radiates electromagnetic energy at a microwave frequency.
12. The apparatus of clause 8, wherein the open channel, in operation, enables passage of the electromagnetic energy and the plasma particles from the exposed surface of the component along the waveguide.
13. The apparatus of clause 8, wherein the material present in the chamber that is transformed is in a gas state.
14. The apparatus of clause 1, wherein the cleaning apparatus includes at least two SWP generators and fewer than 26 SWP generators, with each SWP generator being in contact with a distinct portion of the exposed surface of the component.
15. The apparatus of clause 1, wherein the component includes a conical liner positioned between a collector mirror and an intermediate focus of the collector mirror, the liner including an exposed surface that, when installed, faces EUV light that is reflected from the collector mirror toward the intermediate focus.
16. The apparatus of clause 15, wherein the liner is made of an electrically-conductive material.
17. The apparatus of clause 15, wherein each SWP generator extends along an axial path of the exposed surface of the liner, the axial path extending from the collector mirror side at one end to the intermediate focus side at the other end.
18. The apparatus of clause 1, wherein the component is electrically-conductive.
19. The apparatus of clause 1, wherein the shield is in contact with the SWP generator.
20. A method of cleaning an exposed conducting surface of a component of a chamber of an extreme ultraviolet (EUV) light source, the method comprising:
   removing target debris from the exposed conducting surface of the component without separating the component from the chamber, the removing comprising:
   generating microwave radiation from an antenna that extends axially along a groove formed within the exposed conducting surface;
   enabling the microwave radiation to ionize gas present at the exposed conducting surface to form a surface-wave plasma (SWP) at the exposed conducting surface of the component;
   enabling the generated surface-wave plasma SWP to spread along the exposed conducting surface such that a waveguide is generated between the SWP and the exposed conducting surface; and
   shielding the antenna from EUV radiation and targets within the chamber and dissipating heat away from the antenna.
21. The method of clause 20, wherein the shielding is provided by a shield that extends along the antenna.
22. The method of clause 20, wherein the removing further comprises permitting the microwave radiation and the SWP to escape along the waveguide.
23. The method of clause 20, wherein the exposed conducting surface is grounded.
24. An extreme ultraviolet (EUV) light source comprising:
   a vessel defining a chamber that receives targets at an interaction region;
   a component of the chamber, the component including an exposed surface; and a cleaning apparatus configured to remove target debris from the exposed surface of the component without separating the component from the chamber, the cleaning apparatus comprising:
   one or more surface-wave plasma (SWP) generators, with each SWP generator disposed axially in a groove extending along the exposed surface such that the SWP generator is in contact with a portion of a surface of the groove; and
   for each SWP generator, a shield placed between the chamber and the SWP generator extending over the SWP generator and extending axially along the groove;
   wherein the shield, the SWP generator, and the exposed surface define at least one open channel from the SWP generator to the chamber.
25. The EUV light source of clause 24, wherein the shield is in contact with the SWP generator.
26. The EUV light source of clause 24, wherein the SWP generator comprises an inner electrical conductor extending along an axial path of the groove and a dielectric insulator outside of the inner electrical conductor and extending along the axial path.
27. The EUV light source of clause 26, wherein the dielectric insulator is in contact with at least one surface of the groove and the shield contacts the dielectric insulator.
28. An apparatus comprising:
   a cleaning apparatus configured to remove target debris from an exposed surface of a component of a chamber of an extreme ultraviolet (EUV) light source, without separating the component from the chamber, the cleaning apparatus comprising:
   one or more surface-wave plasma (SWP) generators, with each SWP generator being disposed in a groove formed in the exposed surface of the component; and
   for each SWP generator, a shield placed between the chamber and the SWP generator;
   wherein the shield, the SWP generator, and the exposed surface define at least one open channel between the SWP generator and the chamber, the open channel extending across the groove.
29. An apparatus comprising:
   a debris flow apparatus configured to direct and deposit target debris to one or more surfaces in or adjacent to a chamber of an extreme ultraviolet (EUV) light source; and
   a cleaning apparatus configured to remove the target debris at the one or more surfaces, the cleaning apparatus comprising an active etching device configured to etch the target debris that has been deposited on the one or more surfaces.
30. The apparatus of clause 29, wherein the one or more surfaces comprise one or more of:
   a location within a conical liner positioned between a collector mirror and an intermediate focus of the collector mirror, the liner including an exposed surface that, when installed, faces EUV light that is reflected from the collector mirror toward the intermediate focus;
   a location within the conical liner that is adjacent an exhaust opening fluidly communicating with a removal apparatus; and
   a location within the exhaust opening or the removal apparatus.
31. The apparatus of clause 29, wherein the active etching device comprises at least one of a: surface-wave plasma (SWP) generator, inductively-coupled plasma (ICP) generator, radio-frequency (RF) discharge plasma generator, indirect plasma generator, microwave discharge generator, direct current discharge generator, electron cyclotron resonance plasma generator, and direct plasma generator.
32. The apparatus of clause 29, wherein the debris flow apparatus configured to direct and deposit target debris to one or more surfaces in or adjacent to a chamber of an extreme ultraviolet (EUV) light source comprises one or more gas flows that are directed toward the one or more surfaces.
33. The apparatus of clause 32, wherein the debris flow apparatus comprises a flow controller configured to adjust the one or more gas flows.

1. An apparatus comprising:
a component of a chamber of an extreme ultraviolet (EUV) light source, the component including at least one exposed surface; and
a cleaning apparatus configured to remove debris from the exposed surface of the component without separating the component from the chamber, the cleaning apparatus comprising:
one or more surface-wave plasma (SWP) generators, with each SWP generator being disposed in a groove formed in the exposed surface of the component; and
for each SWP generator, a shield placed between an interior of the chamber and the SWP generator;
wherein the shield, the SWP generator, and the exposed surface define at least one open channel between the SWP generator and the interior of the chamber, the open channel extending across the groove.

2. The apparatus of claim 1, wherein the SWP generator comprises an inner electrical conductor extending along an axial direction of the groove of the component and a dielectric insulator surrounding the inner electrical conductor and extending along the axial direction, the dielectric insulator in contact with a groove surface and the shield in contact with the dielectric insulator.

3. The apparatus of claim 1, wherein the axial direction of the inner electrical conductor is parallel to the exposed surface.

4. The apparatus of claim 1, wherein the shield includes a heat conductive and rigid material that is non-reactive with a target within the chamber that produces EUV light.

5. The apparatus of claim 1, wherein the shield comprises aluminum, aluminum oxide, steel, iron, copper, stainless steel, an alloy of nickel including chromium and iron, molybdenum, or a carbon-based steel alloy.

6. The apparatus of claim 1, wherein each respective shield is positioned with an inner surface in contact with its SWP generator and an outer surface flush with the exposed surface.

7. The apparatus of claim 1, wherein, in operation, each SWP generator radiates electromagnetic energy, which transforms a material that is present in the chamber from a first state into a plasma state that includes plasma particles, and the plasma particles and the exposed surface of the component form a waveguide for the propagation of the electromagnetic energy, the waveguide at least partly in the open channel.

8. The apparatus of claim 7, wherein, in operation, part of the electromagnetic energy continues to transform material present in the chamber at another location along the waveguide into the plasma state that includes plasma particles, and at least some of the plasma particles are free radicals, free electrons, and/or ions of the material, such that the plasma particles come in contact with the debris on the exposed surface of the component.

9. The apparatus of claim 7, wherein each SWP generator radiates electromagnetic energy at a microwave frequency.

10. The apparatus of claim 7, wherein the open channel, in operation, enables passage of the electromagnetic energy and the plasma particles from the exposed surface of the component along the waveguide.

11. The apparatus of claim 1, wherein the cleaning apparatus includes at least two SWP generators and fewer than 26 SWP generators, with each SWP generator being in contact with a distinct portion of the exposed surface of the component.

12. The apparatus of claim 1, wherein the component includes a liner positioned between a collector mirror and an intermediate focus of the collector mirror, the liner including the exposed surface that, when installed, faces EUV light that is reflected from the collector mirror toward the intermediate focus.

13. The apparatus of claim 12, wherein the liner includes an electrically-conductive material.

14. The apparatus of claim 12, wherein each SWP generator extends along an axial path of the exposed surface of the liner, the axial path extending from the collector mirror side at one end to the intermediate focus side at the other end.

15. A method of cleaning an exposed conductive surface of a component of a chamber of an extreme ultraviolet (EUV) light source, the method comprising:
removing debris from the exposed conductive surface of the component without separating the component from the chamber, the removing comprising:
generating microwave radiation from an antenna that extends axially along a groove formed within the exposed conductive surface;
enabling the microwave radiation to ionize gas present at the exposed conductive surface to form a surface-wave plasma (SWP) at the exposed conductive surface of the component;
enabling the SWP to spread along the exposed conductive surface such; and
shielding the antenna from EUV radiation within the chamber and dissipating heat away from the antenna.

16. The method of claim 15, wherein shielding is provided by a shield that extends along the antenna and removing further comprises permitting the microwave radiation and the SWP to escape along the waveguide.

17. The method of claim 15, wherein the exposed conductive surface is grounded.

18. An apparatus comprising:
a gas flow apparatus configured to direct debris to an exhaust opening of a light source; and
a cleaning apparatus configured to remove the debris at an interior surface in a chamber of the light source, the cleaning apparatus comprising an etching device configured to etch the debris deposited on the interior surface.

19. The apparatus of claim 18, wherein the interior surface includes one or more of:
a first location within a conical liner positioned between a collector mirror and an intermediate focus of the collector mirror, the conical liner including an exposed surface facing light that is reflected from the collector mirror toward the intermediate focus;
a second location within the conical liner that is adjacent the exhaust opening fluidly communicating with a removal apparatus; and
a third location within the exhaust opening or the removal apparatus.

20. The apparatus of claim 18, wherein the etching device comprises at least one of a: surface-wave plasma (SWP) generator, inductively-coupled plasma (ICP) generator, radio-frequency (RF) discharge plasma generator, indirect plasma generator, microwave discharge generator, direct current discharge generator, electron cyclotron resonance plasma generator, and direct plasma generator.

21. The apparatus of claim 6, wherein each SWP generator makes contact with a groove surface at at least one interface.

22. The apparatus of claim 12, wherein the liner is a conical liner.

23. The apparatus of claim 1, wherein the component is electrically-conductive.

24. The apparatus of claim 1, wherein the shield is in contact with the SWP generator.
